(19) United States
(12) Patent Application Publication
(10) Pub. No.: US 2024/0431096 A1
(43) Pub. Date: Dec. 26, 2024

(54) SEMICONDUCTOR DEVICE

(71) Applicant: Samsung Electronics Co., Ltd., Suwon-si (KR)

(72) Inventor: Hyungki Cho, Suwon-si (KR)

(21) Appl. No.: 18/487,644

(22) Filed: Oct. 16, 2023

(30) Foreign Application Priority Data
Jun. 21, 2023 (KR) 10-2023-0079689

(51) Int. Cl. H10B 12/00

(52) U.S. Cl. CPC H10B 12/488; H10B 12/315; H10B 12/482

(57) ABSTRACT

Disclosed is a semiconductor device comprising a bit line, a support dielectric layer on the bit line, a first word line and a second word line on the support dielectric layer, a first gate dielectric layer on a first sidewall of the first word line, a second gate dielectric layer on a first sidewall of the second word line, and channel layers that are spaced apart from one another. The support dielectric layer, the first word line, the second word line, the first gate dielectric layer, and the second gate dielectric layer are between a first one of the channel layers and a second one of the channel layers.

### CROSS-REFERENCE TO RELATED APPLICATION

This U.S. nonprovisional application claims priority under 35 U.S.C § 119 to Korean Patent Application No. 10-2023-0079689 filed on Jun. 21, 2023 in the Korean Intellectual Property Office, the disclosure of which is hereby incorporated by reference in its entirety.

### BACKGROUND

The present inventive concepts relate to a semiconductor device, and more particularly, to a semiconductor device including vertical channel transistors.

A reduction in design rule of semiconductor devices induces development of fabrication technology to increase integration, operating speeds, and manufacturing yield of semiconductor devices. Accordingly, transistors with vertical channels have been suggested to increase their integration, resistance, current driving capability, etc.

### SUMMARY

Some embodiments of the present inventive concepts provide a semiconductor device with improved electrical properties and increased integration.

According to some embodiments of the present inventive concepts, a semiconductor device may include a bit line, a support dielectric layer on the bit line, a first word line and a second word line on the support dielectric layer, a first gate dielectric layer on a first sidewall of the first word line, a second gate dielectric layer on a first sidewall of the second word line, and channel layers that are spaced apart from one another. The support dielectric layer, the first word line, the second word line, the first gate dielectric layer, and the second gate dielectric layer may be between a first one of the channel layers and a second one of the channel layers.

According to some embodiments of the present inventive concepts, a semiconductor device may include a plurality of gate structures, a channel layer between a first one of the plurality of gate structures and a second one of the plurality of gate structures, and a bit line in contact with the channel layer. Each of the plurality of gate structures may include a first word line and a second word line that are spaced apart from each other, a first gate dielectric layer on a first sidewall of the first word line, a second gate dielectric layer on a first sidewall of the second word line, and a gate capping layer in contact with a top surface of the first word line, a top surface of the second word line, a top surface of the first gate dielectric layer, and a top surface of the second gate dielectric layer.

According to some embodiments of the present inventive concepts, a semiconductor device may include a bit line, a gate structure on the bit line, channel layers that are spaced apart from each other with the gate structure between a first one of the channel layers and a second one of the channel layers, a landing pad electrically connected to each of the channel layers, a data storage pattern electrically connected to the landing pad. The gate structure may include: a support dielectric layer on the bit line, a first word line and a second word line that are spaced apart from each other on the support dielectric layer, a first gate dielectric layer on a sidewall of the first word line, a second gate dielectric layer on a sidewall of the second word line, and a gate capping layer in contact with the first word line, the second word line, the first gate dielectric layer, and the second gate dielectric layer.

### BRIEF DESCRIPTION OF DRAWINGS

FIG. 1 illustrates a block diagram showing a semiconductor device according to some embodiments.

FIGS. 2 and 3 illustrate simplified perspective views showing a semiconductor device according to some embodiments.

FIG. 4A illustrates a plan view showing a semiconductor device according to some embodiments.

FIG. 4B illustrates a cross-sectional view taken along line A-A′ of FIG. 4A.

FIG. 4C illustrates a cross-sectional view taken along line B-B′ of FIG. 4A.

FIG. 4D illustrates a cross-sectional view taken along line C-C′ of FIG. 4A.

FIGS. 5A, 5B, 5C, 5D, 6A, 6B, 6C, 7A, 7B, 7C, 8A, 8B, 8C, 9A, 9B, 9C, 9D, 10A, 10B, 10C, 11A, 11B, 12A, 12B, 13A, 13B, 13C, 14A, 14B, 14C, 15A, 15B, 15C, 16A, 16B, 16C, 17A, 17B, 17C, 17D, 18A, 18B, 19A, 19B, and 19C illustrate plan and cross-sectional views showing a method of fabricating a semiconductor device according to some embodiments.

FIG. 20 illustrates a cross-sectional view showing a semiconductor device according to some embodiments.

FIG. 21 illustrates a cross-sectional view showing a semiconductor device according to some embodiments.

FIG. 22 illustrates a cross-sectional view showing a semiconductor device according to some embodiments.

FIG. 23 illustrates a cross-sectional view showing a semiconductor device according to some embodiments.

FIG. 24 illustrates a cross-sectional view showing a semiconductor device according to some embodiments.

FIG. 25 illustrates a cross-sectional view showing a semiconductor device according to some embodiments.

FIG. 26 illustrates a cross-sectional view showing a semiconductor device according to some embodiments.

### DETAILED DESCRIPTION

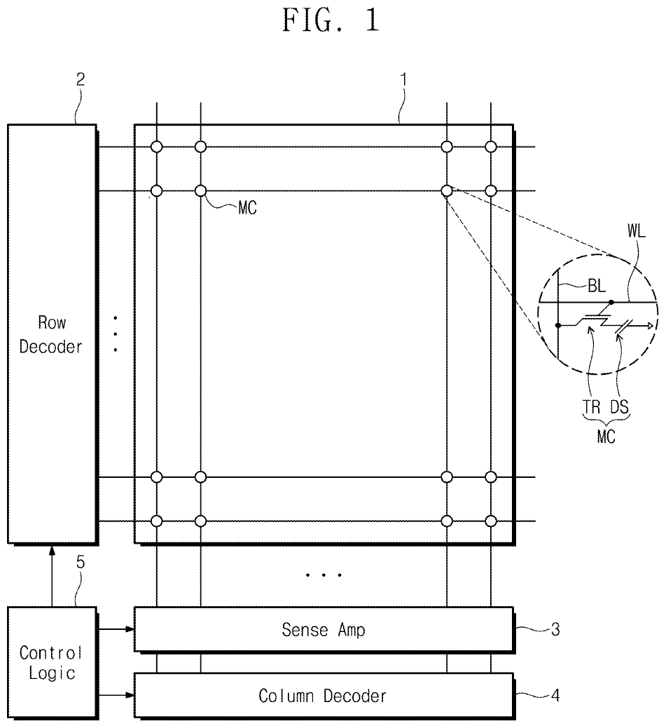

FIG. 1 illustrates a block diagram showing a semiconductor device according to some embodiments.

Referring to FIG. 1, a semiconductor device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the memory cells MC may be connected between a word line WL a bit line BL that intersect each other.

Each of the memory cells MC may include a selection element TR and a data storage element DS. The selection element TR and the data storage element DS may be electrically connected to each other. The selection element TR may be connected to both the word line WL and the bit line BL. For example, the selection element TR may be provided at an intersection between the word line WL and the bit line BL.

The selection element TR may include a field effect transistor. The data storage element DS may include a capacitor, a magnetic tunnel junction pattern, or a variable resistor. For example, a gate terminal of a transistor as the selection element TR may be connected to the word line WL, and source/drain terminals of the transistor may be connected to the bit line BL and the data storage element DS.

The row decoder 2 may decode an address input received from external to the row decoder 2, and may select one of the word lines WL of the memory cell array 1. The address decoded in the row decoder 2 may be provided to a row driver (not shown), and in response to a control operation from control circuits, the row driver may provide a certain voltage to a selected word line WL and each of the non-selected word lines WL.

In response to an address decoded from the column decoder 4, the sense amplifier 3 may detect and amplify a voltage difference between a selected bit line BL and a reference bit line, and may then output the amplified voltage difference.

The column decoder 4 may provide a data delivery pathway between the sense amplifier 3 and an external device (e.g., a memory controller). The column decoder 4 may decode an address externally input and may select one of the bit lines BL.

The control logic 5 may generate control signals that control operations to write data to the memory cell array 1 and/or to read data from the memory cell array 1.

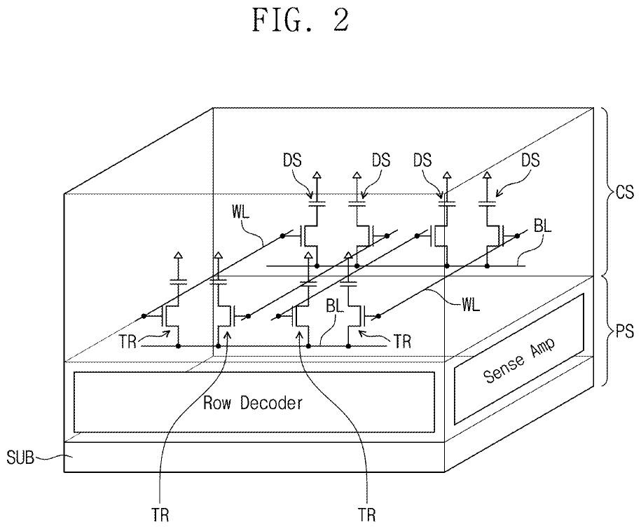

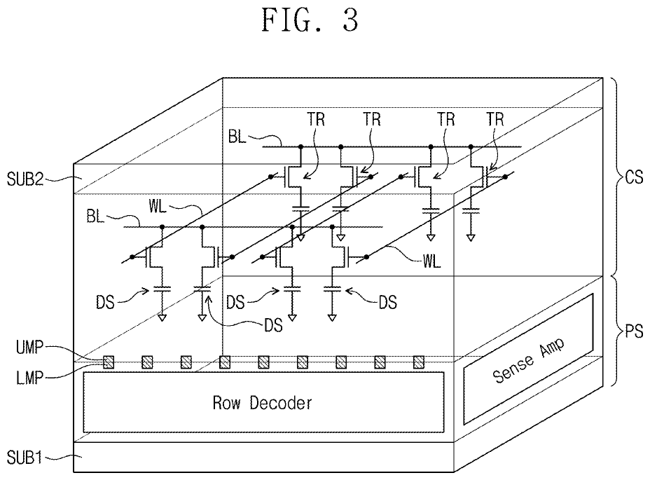

FIGS. 2 and 3 illustrate simplified perspective views showing a semiconductor device according to some embodiments.

Referring to FIGS. 2 and 3, a semiconductor device may include a peripheral circuit structure PS and a cell array structure CS connected (e.g., electrically connected) to the peripheral circuit structure PS.

The peripheral circuit structure PS may include core/peripheral circuits formed on a substrate SUB. The core/peripheral circuits may include the row and column decoders 2 and 4, the sense amplifier 3, and the control logics 5 that are discussed with reference to FIG. 1.

The cell array structure CS may include the memory cell array (see 1 of FIG. 1) including the memory cells (see MC of FIG. 1) that are arranged two-dimensionally or three-dimensionally. Each of the memory cells (see MC of FIG. 1) may include, as discussed above, a selection element TR and a data storage element DS.

According to some embodiments, a vertical channel transistor (VCT) may be adopted as the selection element TR of each of the memory cells (see MC of FIG. 1). The vertical channel transistor may include a channel whose lengthwise direction is perpendicular to a top surface of the substrate SUB. A capacitor may be adopted as the data storage element DS of each of the memory cells (see MC of FIG. 1).

In the embodiments of FIG. 2, the peripheral circuit structure PS may be provided on the substrate SUB, and the cell array structure CS may be provided on the peripheral circuit structure PS.

In the embodiments of FIG. 3, the peripheral circuit structure PS may be provided on a first substrate SUB1, and the cell array structure CS may be provided on a second substrate SUB2. The first substrate SUB1 and the second substrate SUB2 may face each other.

The peripheral circuit structure PS may be provided on its uppermost portion with first metal pads LMP. The first metal pads LMP may be electrically connected to the core/peripheral circuits (see 2, 3, 4, and 5 of FIG. 1).

The cell array structure CS may be provided on its lowermost portion with second metal pads UMP. The second metal pads UMP may be electrically connected to the memory cell array (see 1 of FIG. 1). The second metal pads UMP may be in direct contact with or bonded to the first metal pads LMP of the peripheral circuit structure PS.

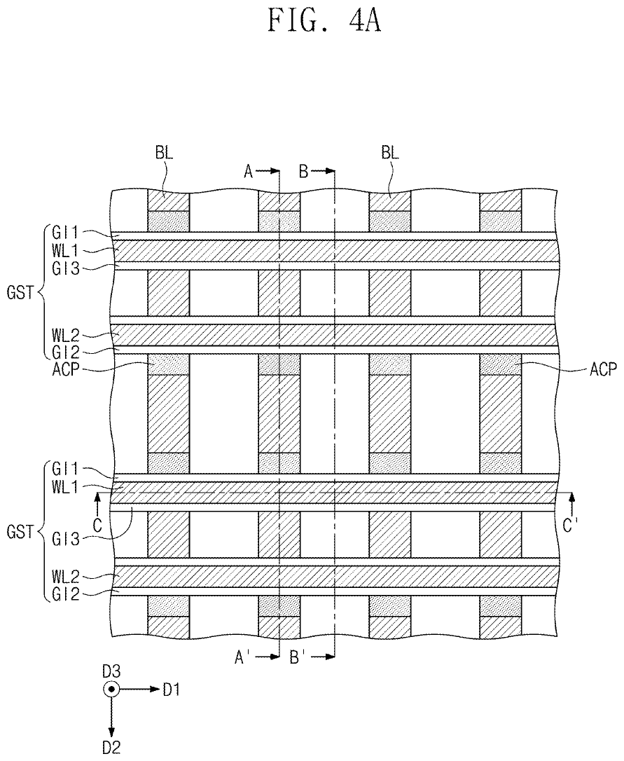

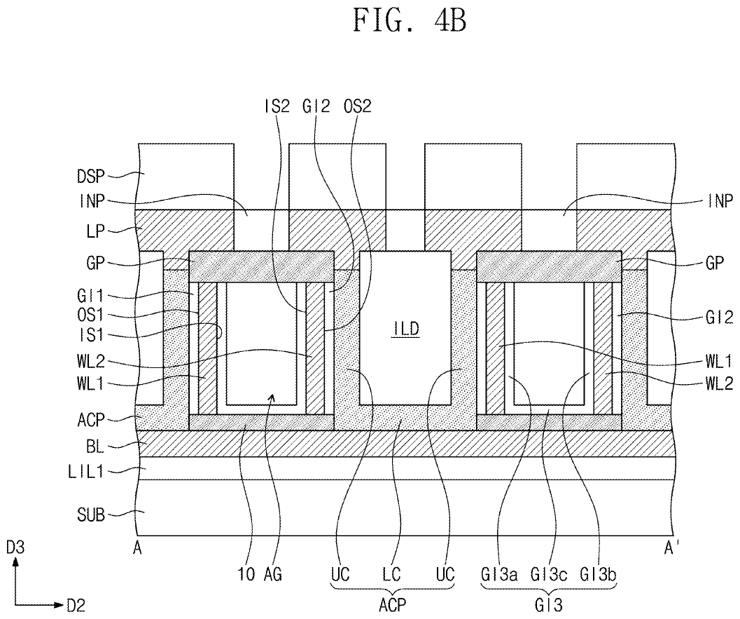

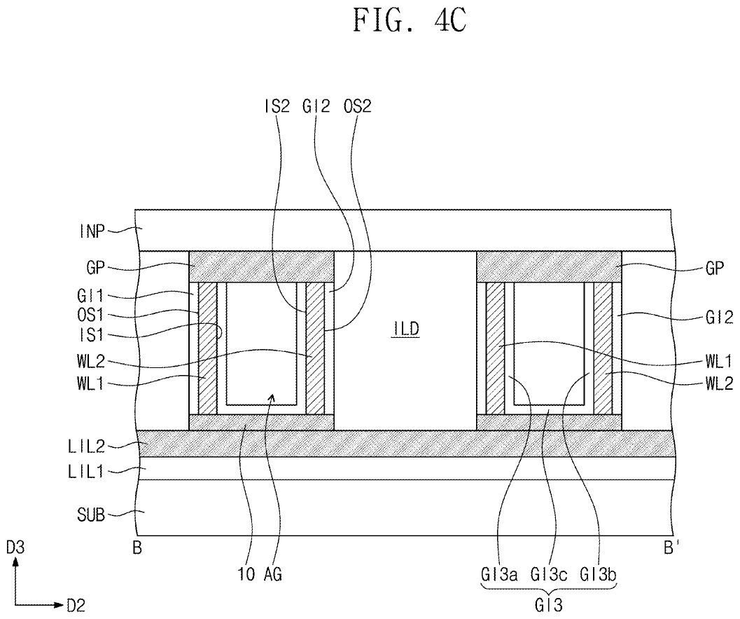

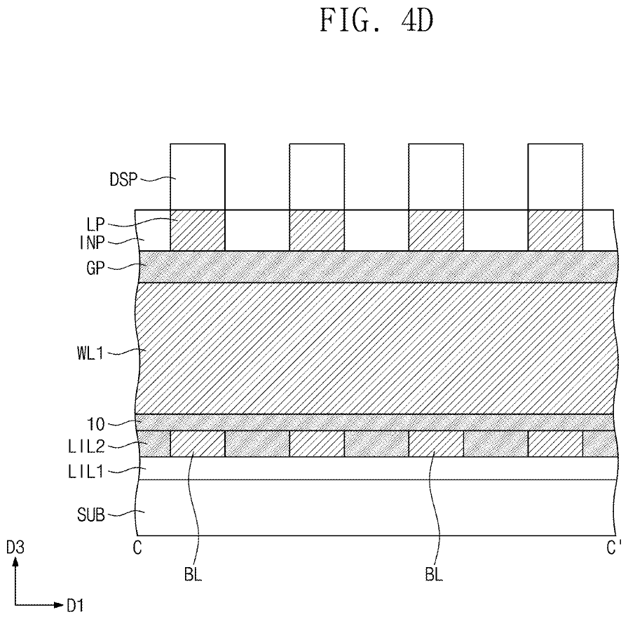

FIG. 4A illustrates a plan view showing a semiconductor device according to some embodiments. FIG. 4B illustrates a cross-sectional view taken along line A-A′ of FIG. 4A. FIG. 4C illustrates a cross-sectional view taken along line B-B′ of FIG. 4A. FIG. 4D illustrates a cross-sectional view taken along line C-C′ of FIG. 4A.

Referring to FIGS. 4A to 4D, a first lower dielectric layer LIL1 may be provided on a substrate SUB. The substrate SUB may have a plate shape that expands along a plane defined by a first direction D1 and a second direction D2. The first direction D1 and the second direction D2 may intersect each other. For example, the first direction D1 and the second direction D2 may be horizontal directions that are orthogonal to each other. The first lower dielectric layer LIL1 may include a dielectric material. For example, the first lower dielectric layer LIL1 may include oxide.

In some embodiments, the substrate SUB and the first lower dielectric layer LIL1 may be provided therebetween with the peripheral circuit structure PS discussed with reference to FIG. 2. For example, an integrated circuit, such as a logic device, may be provided between the substrate SUB and the first lower dielectric layer LIL1.

A second lower dielectric layer LIL2 may be provided on the first lower dielectric layer LIL1. A plurality of bit lines BL may be provided in the second lower dielectric layer LIL2. The bit lines BL may extend in the second direction D2. The bit lines BL may be arranged along the first direction D1. The bit lines BL may be spaced apart from each other in the first direction D1.

The bit lines BL may include a conductive material. For example, the bit lines BL may include at least one selected from doped semiconductor materials (e.g., doped silicon or doped germanium), conductive metal nitrides (e.g., titanium nitride or tantalum nitride), metals (e.g., tungsten, titanium, or tantalum), and/or metal-semiconductor compounds (e.g., tungsten silicide, cobalt silicide, or titanium silicide). The bit line BL may be a single conductive layer or a multiple conductive layer. The second lower dielectric layer LIL2 may include a dielectric material. For example, the second lower dielectric layer LIL2 may include nitride.

The bit lines BL may be provided with channel layers ACP thereon. A plurality of channel layers ACP may be in contact with one bit line BL. The channel layers ACP provided on one bit line BL may be arranged along the second direction D2.

The channel layer ACP may include a lower channel portion LC and two upper channel portions UC. The lower channel portion LC may be provided on a top surface of the bit line BL. The lower channel portion LC may extend in the second direction D2. The upper channel portions UC may be provided on the lower channel portion LC. The upper channel portions UC may be connected to the lower channel portion LC. The two upper channel portions UC of one channel layers ACP may be spaced apart from each other in the second direction D2. The upper channel portion UP may extend in a third direction D3. The third direction D3 may intersect the first direction D1 and the second direction D2. For example, the third direction D3 may be a vertical direction perpendicular to the first direction D1 and the second direction D2.

The channel layer ACP may include a semiconductor material. For example, the channel layer ACP may include an oxide semiconductor material, and for example, the oxide semiconductor material may include at least one selected from InGaZnO, InGaSiO, InSnZnO, InZnO, ZnO, ZnSnO, ZnON, ZrZnSnO, SnO, HfInZnO, GaZnSnO, AlZnSnO, YbGaZnO, and/or InGaO. In some embodiments, the channel layer ACP may be a multiple layer including a plurality of material layers. For example, the channel layer ACP may include a two-dimensional material.

Gate structures GST may be provided on the bit lines BL and the second lower dielectric layer LIL2. The gate structure GST may extend in the first direction D1. The gate structures GST may be arranged in the second direction D2. The channel layer ACP may be provided between the gate structures GST that are adjacent to each other in the second direction D2. The channel layers ACP adjacent to each other in the second direction D2 may be spaced apart from each other across the gate structure GST.

The gate structure GST may include a support dielectric layer 10, a first word line WL1, a second word line WL2, a first gate dielectric layer GI1, a second gate dielectric layer GI2, a third gate dielectric layer GI3, and a gate capping layer GP. The support dielectric layer 10, the first word line WL1, the second word line WL2, the first gate dielectric layer GI1, the second gate dielectric layer GI2, the third gate dielectric layer GI3, and the gate capping layer GP included in one bit line BL may be provided between the channel layers ACP that are adjacent to each other in the second direction D2.

The support dielectric layer 10 may be in contact with the top surface of the bit line BL. The support dielectric layer 10 may extend in the first direction D1. The support dielectric layer 10 may have a bottom surface coplanar with that of the lower channel portion LC of the channel layer ACP (i.e., a substantially equal height with respect to the substrate). The lower channel portion LC of the channel layer ACP may be provided between the support dielectric layers 10 that are adjacent to each other in the second direction D2. The support dielectric layer 10 may include a dielectric material. For example, the support dielectric layer 10 may include nitride.

The first word line WL1 and the second word line WL2 may be provided on the support dielectric layer 10. The first word line WL1 and the second word line WL2 may have bottom surfaces in contact with a top surface of the support dielectric layer 10. The first word line WL1 and the second word line WL2 may be spaced apart from each other in the second direction D2. The first word line WL1 and the second word line WL2 may extend in the first direction D1.

The first and second word lines WL1 and WL2 may include a conductive material. For example, the first and second word lines WL1 and WL2 may include at least one selected from doped semiconductor materials (e.g., doped silicon or doped germanium), conductive metal nitrides (e.g., titanium nitride or tantalum nitride), metals (e.g., tungsten, titanium, or tantalum), and/or metal-semiconductor compounds (e.g., tungsten silicide, cobalt silicide, or titanium silicide).

The first word line WL1 may have an inner sidewall IS1 and an outer sidewall OS1. The second word line WL2 may include an inner sidewall IS2 and an outer sidewall OS2. The inner sidewall IS1 of the first word line WL1 may face the inner sidewall IS2 of the second word line WL2. Adjacent sidewalls of the first word line WL1 and the second word line WL2 may be the inner sidewalls IS1 and IS2 of the first word line WL1 and the second word line WL2. The outer sidewall OS1 of the first word line WL1 may stand opposite to the inner sidewall IS1 of the first word line WL1. The outer sidewall OS2 of the second word line WL2 may stand opposite to the inner sidewall IS2 of the second word line WL2. The inner sidewall IS1 and the outer sidewall OS1 of the first word line WL1 may extend in the first direction D1, and likewise the inner sidewall IS2 and the outer sidewall OS2 of the second word line WL2 may extend in the first direction D1.

The first gate dielectric layer GI1 may be provided on the outer sidewall OS1 of the first word line WL1. The first gate dielectric layer GI1 may be in contact with the outer sidewall OS1 of the first word line WL1. The first gate dielectric layer GI1 may extend in the first direction D1. The first gate dielectric layer GI1 may have a bottom surface in contact with the top surface of the support dielectric layer 10. The first gate dielectric layer GI1 may be provided between the first word line WL1 and the upper channel portion UC of the channel layer ACP. The first gate dielectric layer GI1 may have a sidewall coplanar with that of the support dielectric layer 10.

The second gate dielectric layer GI2 may be provided on the outer sidewall OS2 of the second word line WL2. The second gate dielectric layer GI2 may be in contact with the outer sidewall OS2 of the second word line WL2. The second gate dielectric layer GI2 may extend in the first direction D1. The second gate dielectric layer GI2 may have a bottom surface in contact with the top surface of the support dielectric layer 10. The second gate dielectric layer GI2 may be provided between the second word line WL2 and the upper channel portion UC of the channel layer ACP. The second gate dielectric layer GI2 may have a sidewall coplanar with that of the support dielectric layer 10.

The third gate dielectric layer GI3 may be provided between the first word line WL1 and the second word line WL2. The third gate dielectric layer GI3 may extend in the first direction D1. The third gate dielectric layer GI3 may include a first portion GI3a in contact with the inner sidewall IS1 of the first word line WL1, a second portion GI3b in contact with the inner sidewall IS2 of the second word line WL2, and a third portion GI3c in contact with the top surface of the support dielectric layer 10. The third portion GI3c of the third gate dielectric layer GI3 may physically connect or be in direct contact to each other the first and second portions GI3a and GI3b of the third gate dielectric layer GI3. The first and second portions GI3a and GI3b of the third gate dielectric layer GI3 may be provided on the third portion GI3c of the third gate dielectric layer GI3. The first and second portions GI3a and GI3b of the third gate dielectric layer GI3 may be spaced apart from each other in the second direction D2. A width in the second direction D2 of the first and second portions GI3a and GI3b of the third gate dielectric layer GI3 may be less than a width in the second direction D2 of the third portion GI3c of the third gate dielectric layer GI3. The first word line WL1, the second word line WL2, and the third gate dielectric layer GI3 may be provided between the first gate dielectric layer GI1 and the second gate dielectric layer GI2.

The first, second, and third gate dielectric layers GI1, GI2, and GI3 may include a dielectric material. For example, the first, second, and third gate dielectric layers GI1, GI2, and GI3 may include oxide.

The gate capping layer GP may be provided on the first and second word lines WL1 and WL2 and the first, second, and third gate dielectric layers GI1, GI2, and GI3. The gate capping layer GP may have a bottom surface in contact with top surfaces of the first and second word lines WL1 and WL2, top surfaces of the first and second gate dielectric layers GI1 and GI2, and top surfaces of the first and second portions GI3a and GI3b of the third gate dielectric layer GI3. The top surfaces of the first and second word lines WL1 and WL2 may be coplanar with the top surfaces of the first and second gate dielectric layers GI1 and GI2 and the top surfaces of the first and second portions GI3a and GI3b of the third gate dielectric layer GI3 (i.e., a substantially equal height with respect to the substrate). The top surfaces of the first and second word lines WL1 and WL2, the top surfaces of the first and second gate dielectric layers GI1 and GI2, and the top surfaces of the first and second portions GI3a and GI3b of the third gate dielectric layer GI3 may be located at a level lower than that of a top surface of the upper channel portion UC of the channel layer ACP with respect to the substrate SUB.

The gate capping layer GP may have a sidewall coplanar with the sidewall of the first gate dielectric layer GI1 and the sidewall of the second gate dielectric layer GI2. The sidewall of the gate capping layer GP may be in contact with the upper channel portion of the channel layer ACP. The gate capping layer GP may include a dielectric material. For example, the gate capping layer GP may include nitride.

A cavity or air gap AG may be defined in the gate structure GST. The air gap AG may be defined between the first and second word lines WL1 and WL2. The air gap AG may be surrounded by the third gate dielectric layer GI3 and the gate capping layer GP of the gate structure GST in a cross-sectional view. The air gap AG may have a bottom surface defined by a top surface of the third portion GI3c of the third gate dielectric layer GI3. The air gap AG may have sidewalls defined by sidewalls of the first and second portions GI3a and GI3b of the third gate dielectric layer GI3. The air gap AG may have a top surface defined by the bottom surface of the gate capping layer GP. The air gap AG may be, for example, an empty space filled with air. It will be understood that “air gap” may be, for example, any void or cavity, and may be a gap filled with air (e.g., an air-gap), a gap filled with an inert gas or gases (e.g., an inert gas gap), a gap defining a vacuum (e.g., a vacuum gap), etc.

A plurality of dielectric layers ILD may be provided. The dielectric layer ILD may be provided between neighboring gate structures GST. The dielectric layer ILD may be provided on the channel layers ACP that are arranged in the first direction D1. The dielectric layer ILD may be in contact with a sidewall of the upper channel portion UC and a top surface of the lower channel portion LC. The dielectric layer ILD may include a dielectric material. For example, the dielectric layers ILD may include oxide.

A plurality of landing pads LP may be provided on the channel layers ACP. The landing pad LP may be connected to the top surface of the upper channel portion UC of the channel layer ACP. The landing pad LP may be spaced apart from the first, second, and third gate dielectric layers GI1, GI2, and GI3. The landing pad LP may include a conductive material. For example, the landing pad LP may include at least one selected from doped semiconductor materials (e.g., doped silicon or doped germanium), conductive metal nitrides (e.g., titanium nitride or tantalum nitride), metals (e.g., tungsten, titanium, or tantalum), and/or metal-semiconductor compounds (e.g., tungsten silicide, cobalt silicide, or titanium silicide).

A dielectric pattern INP may be provided between the landing pads LP. The dielectric pattern INP may be provided on the gate capping layer GP. The dielectric pattern INP may separate the landing pads LP from each other. The dielectric pattern INP may include a dielectric material. In some embodiments, the dielectric pattern INP may be a multiple layer including a plurality of dielectric layers.

A plurality of data storage patterns DSP may be correspondingly connected to the landing pads LP. The data storage patterns DSP may be electrically connected through the landing pads LP to the channel layer ACP.

In some embodiments, the data storage pattern DSP may be a capacitor. In this case, the data storage pattern DSP may include a bottom electrode, a top electrode, and a capacitor dielectric layer interposed between the bottom and top electrodes.

In some embodiments, the data storage pattern DSP may be a variable resistance pattern whose two resistance states are switched due to an electrical pulse. For example, the data storage pattern DSP may include a phase-change material whose crystalline state is changed based on an amount of current, perovskite compounds, transition metal oxide, magnetic materials, ferromagnetic materials, or antiferromagnetic materials.

In a semiconductor device according to some embodiments, as the cavity or air gap AG is provided between the first and second word lines WL1 and WL2, there may be a reduction in parasitic capacitance between the first and second word lines WL1 and WL2, and there may also be an improvement in alternating current properties of the semiconductor device.

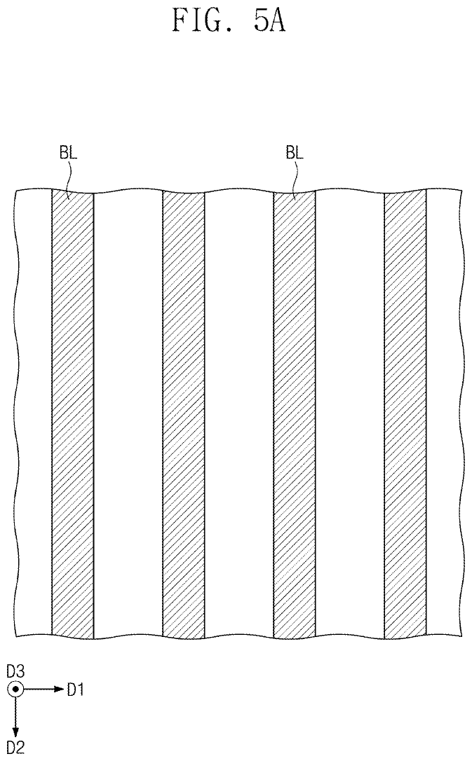

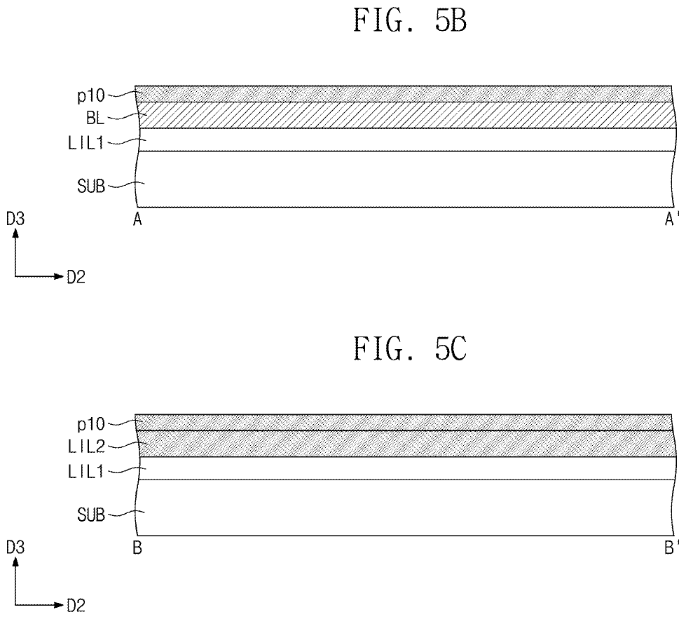

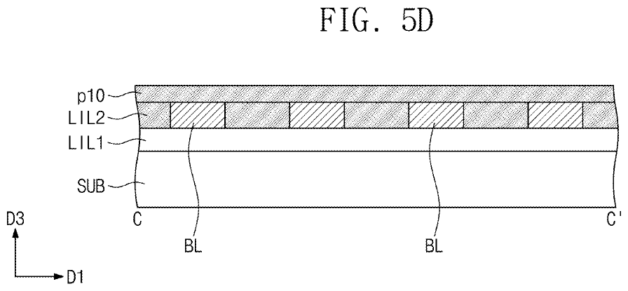

FIGS. 5A, 5B, 5C, 5D, 6A, 6B, 6C, 7A, 7B, 7C, 8A, 8B, 8C, 9A, 9B, 9C, 9D, 10A, 10B, 10C, 11A, 11B, 12A, 12B, 13A, 13B, 13C, 14A, 14B, 14C, 15A, 15B, 15C, 16A, 16B, 16C, 17A, 17B, 17C, 17D, 18A, 18B, 19A, 19B, and 19C illustrate plan and cross-sectional views showing a method of fabricating a semiconductor device according to some embodiments.

Referring to FIGS. 5A, 5B, 5C, and 5D, a first lower dielectric layer LIL1 may be formed on a substrate SUB. A second lower dielectric layer LIL2 may be formed on the first lower dielectric layer LIL1. A plurality of bit lines BL may be formed in the second lower dielectric layer LIL2. The formation of the bit lines BL may include etching the second lower dielectric layer LIL2 to form trenches and forming the bit lines BL to fill the trenches.

A preliminary support dielectric layer p10 may be formed on the bit lines BL and the second lower dielectric layer LIL2. The preliminary support dielectric layer p10 may include a dielectric material.

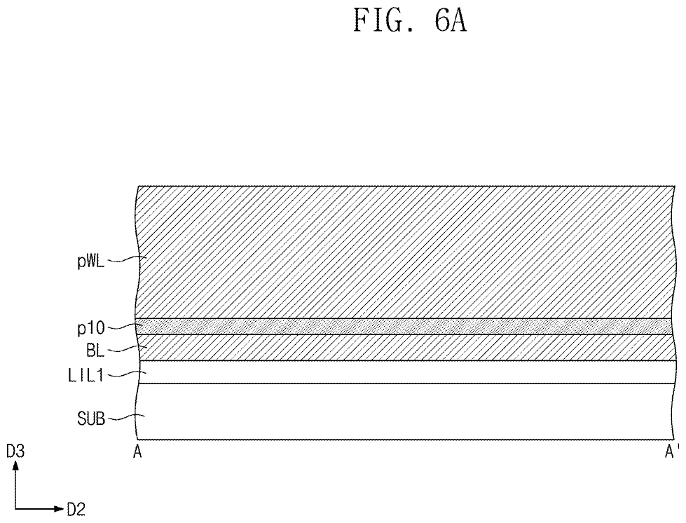

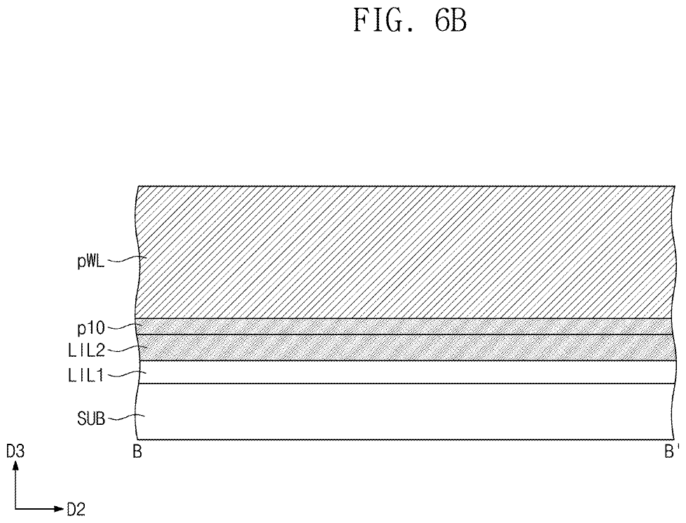

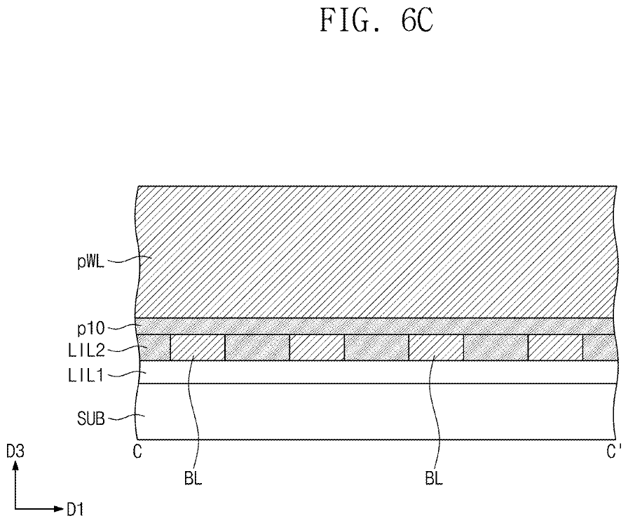

Referring to FIGS. 6A, 6B, and 6C, a preliminary word-line layer pWL may be formed on the preliminary support dielectric layer p10. The preliminary word-line layer pWL may include a conductive material.

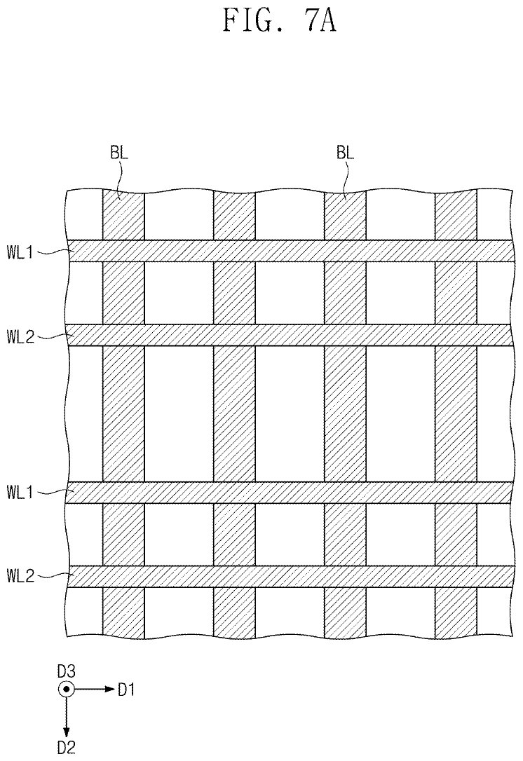

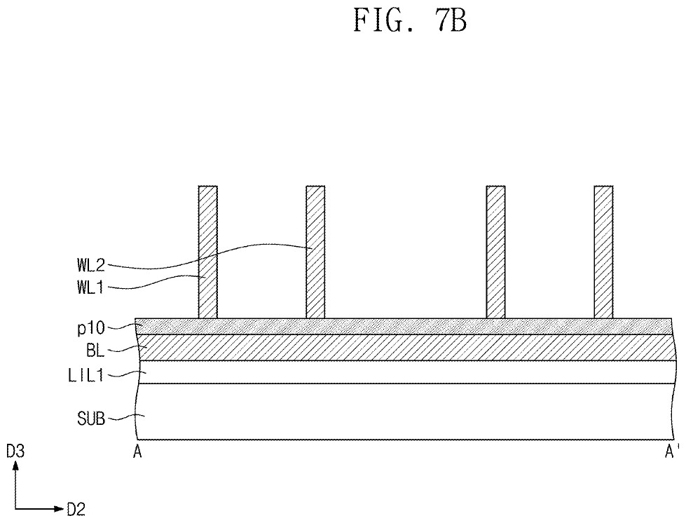

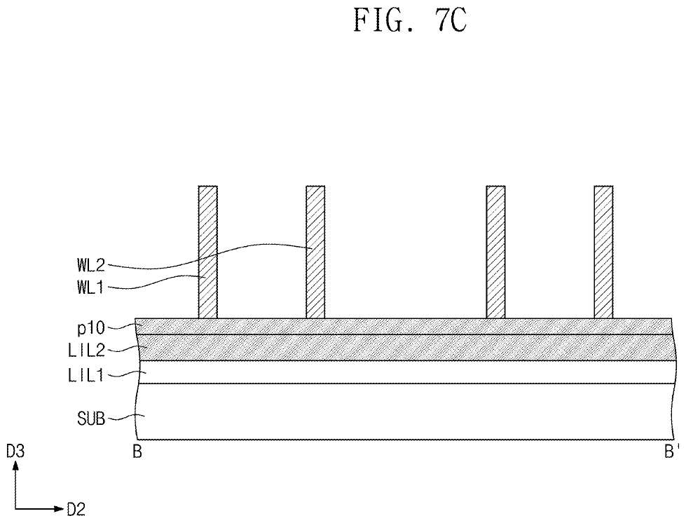

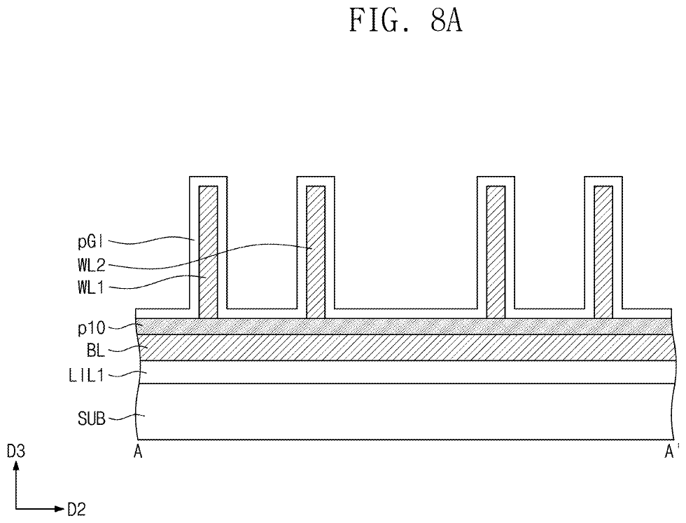

Referring to FIGS. 7A, 7B, and 7C, the preliminary word-line layer pWL may be patterned to form first word lines WL1 and second word lines WL2. In some embodiments, the patterning of the preliminary word-line layer pWL may include forming photoresist patterns on the preliminary word-line layer pWL, and using the photoresist patterns as an etching mask to pattern the preliminary word-line layer pWL.

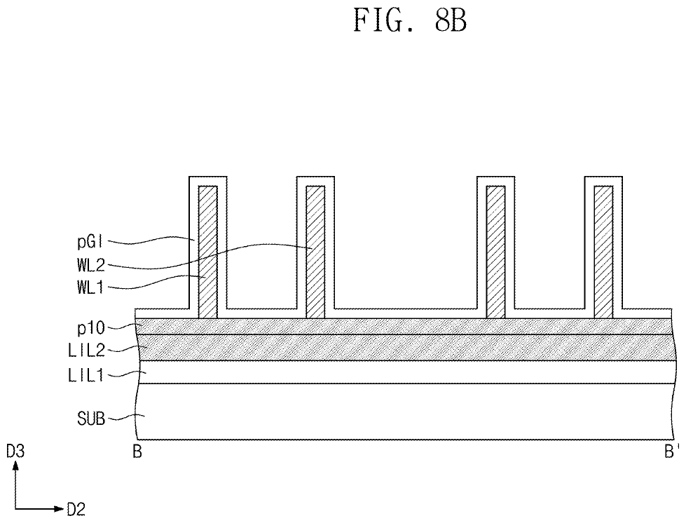

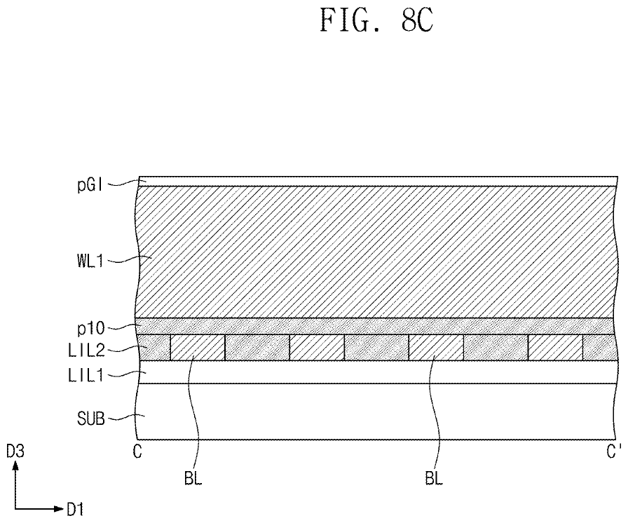

Referring to FIGS. 8A, 8B, and 8C, a preliminary gate dielectric layer pGI may be formed. The preliminary gate dielectric layer pGI may be conformally formed on the preliminary support dielectric layer p10, the first word lines WL1, and the second word lines WL2.

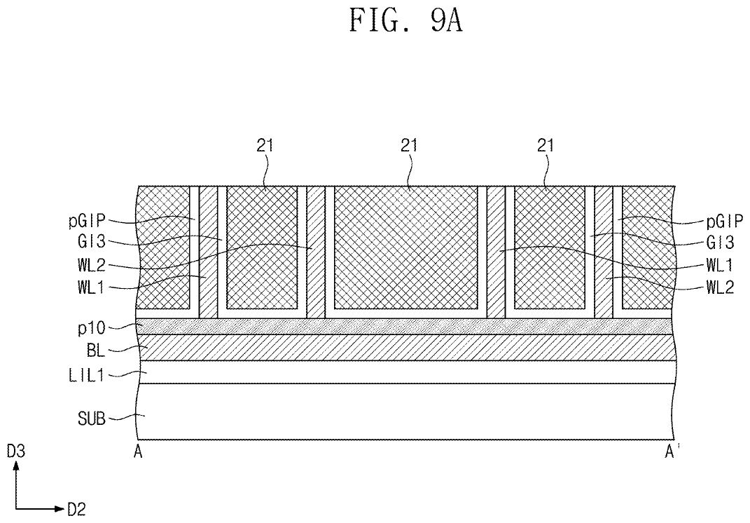

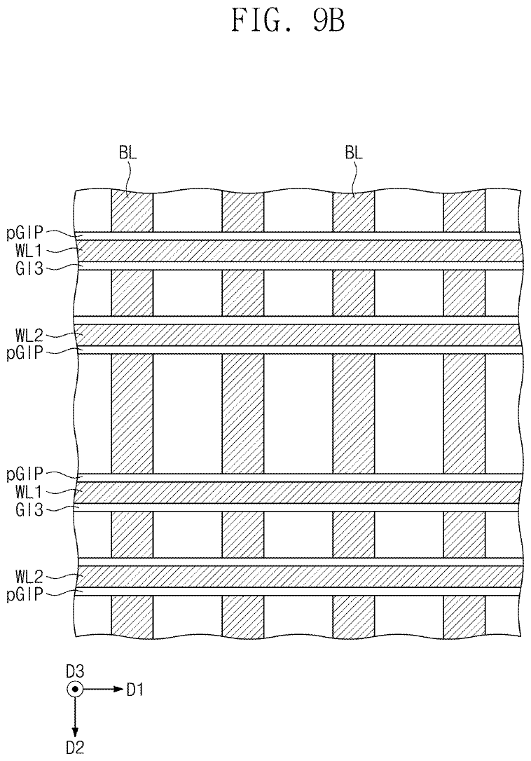

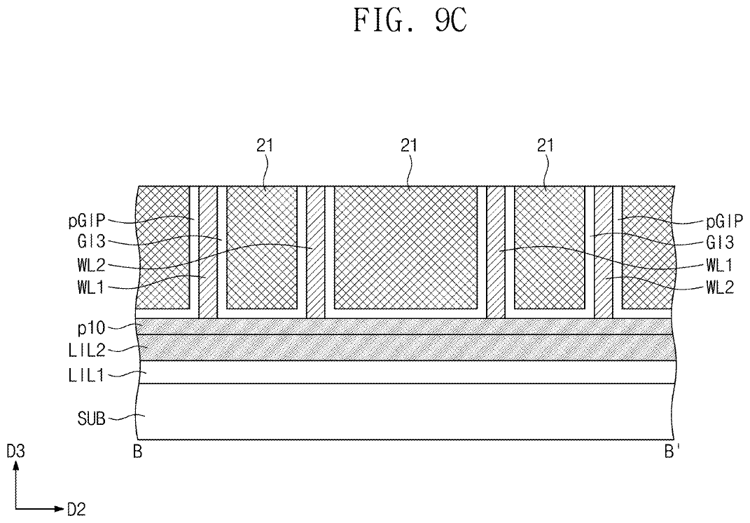

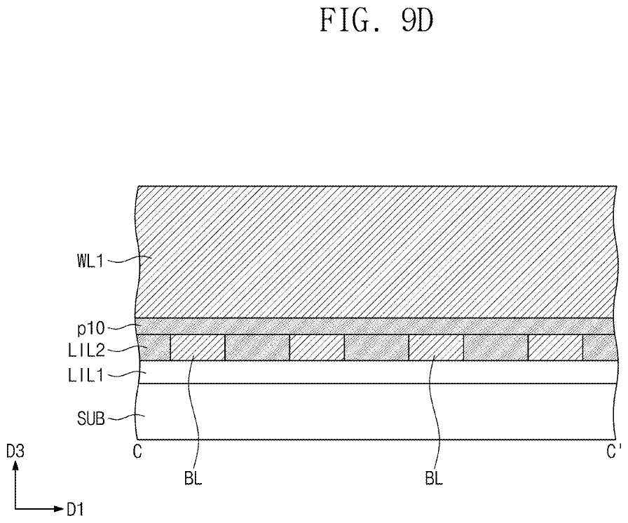

Referring to FIGS. 9A, 9B, 9C, and 9D, there may be formed first sacrificial layers 21, preliminary gate dielectric patterns pGIP, and third gate dielectric layer GI3. The formation of the first sacrificial layers 21, the preliminary gate dielectric patterns pGIP, and the third gate dielectric layer GI3 may include forming a preliminary sacrificial layer on the preliminary gate dielectric layer pGI, and removing an upper portion of the preliminary sacrificial layer and an upper portion of the preliminary gate dielectric layer pGI. In some embodiments, a chemical mechanical polishing process may be employed to remove the upper portion of the preliminary sacrificial layer and the upper portion of the preliminary gate dielectric layer pGI.

The upper portion of the preliminary gate dielectric layer pGI may be removed such that the preliminary gate dielectric layer pGI may be divided into the preliminary gate dielectric patterns pGIP and the third gate dielectric layers GI3. The upper portion of the preliminary sacrificial layer may be removed such that the preliminary sacrificial layer may be divided into the first sacrificial layers 21. The first sacrificial layer 21 may include a dielectric material. For example, the first sacrificial layer 21 may include spin-on-hardmask (SOH).

The upper portion of the preliminary sacrificial layer and the upper portion of the preliminary gate dielectric layer pGI may be removed to expose top surfaces of the first and second word lines WL1 and WL2.

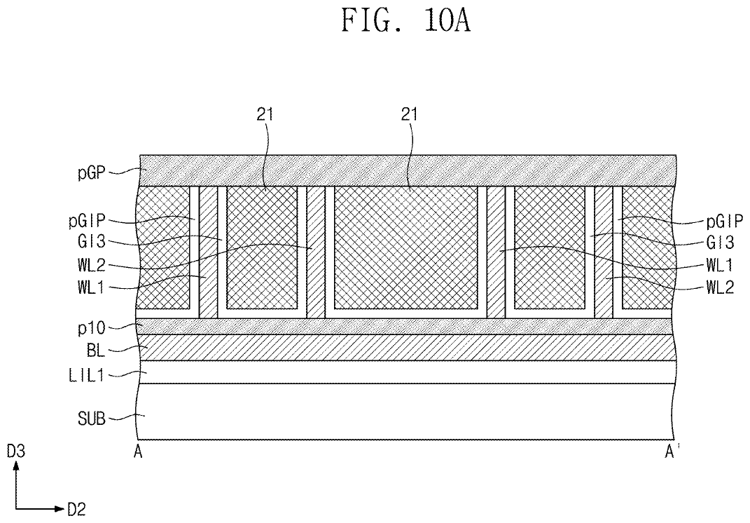

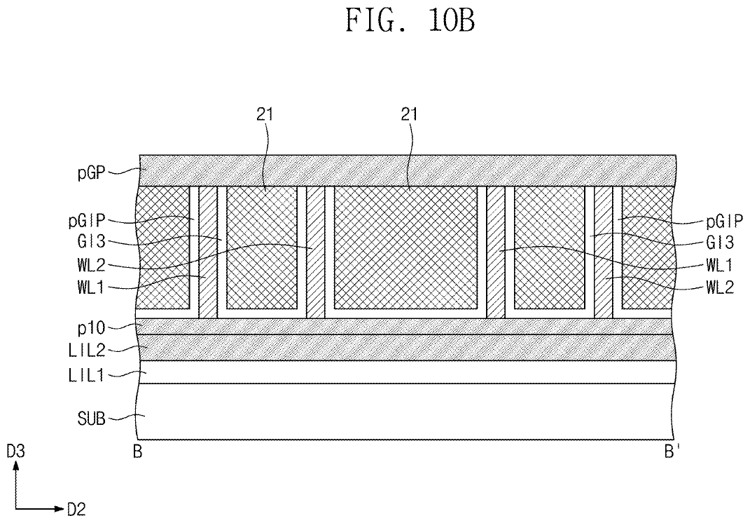

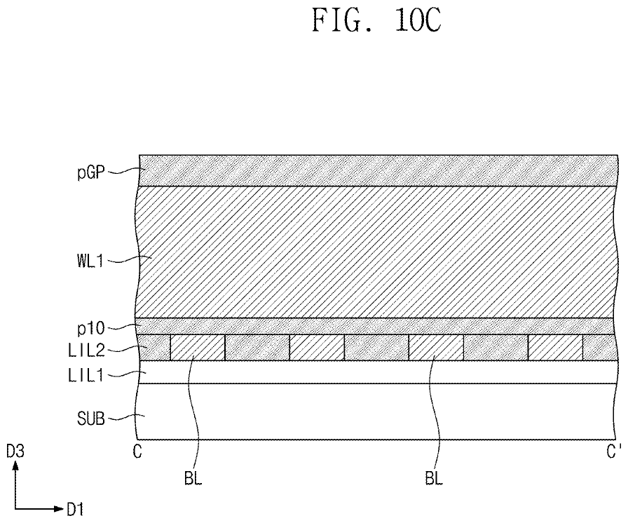

Referring to FIGS. 10A, 10B, and 10C, a preliminary gate capping layer pGP may be formed. The preliminary gate capping layer pGP may cover or overlap the first sacrificial layers 21, the third gate dielectric layers GI3, the preliminary gate dielectric patterns pGIP, the first word lines WL1, and the second word lines WL2. The preliminary gate capping layer pGP may include a dielectric material.

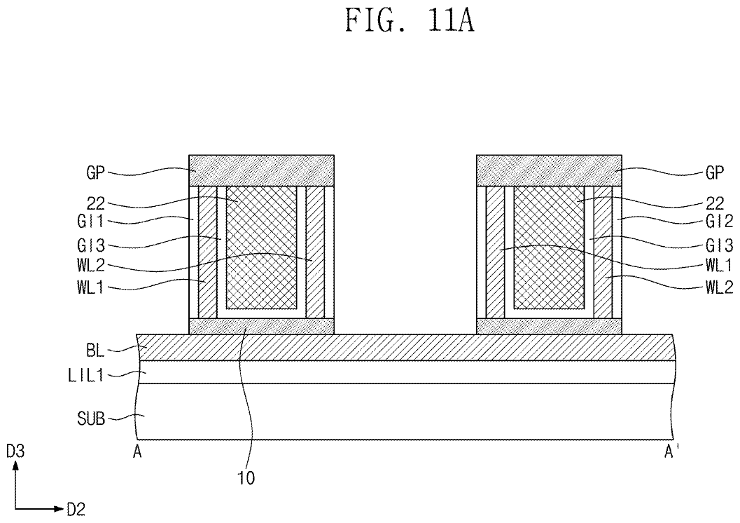

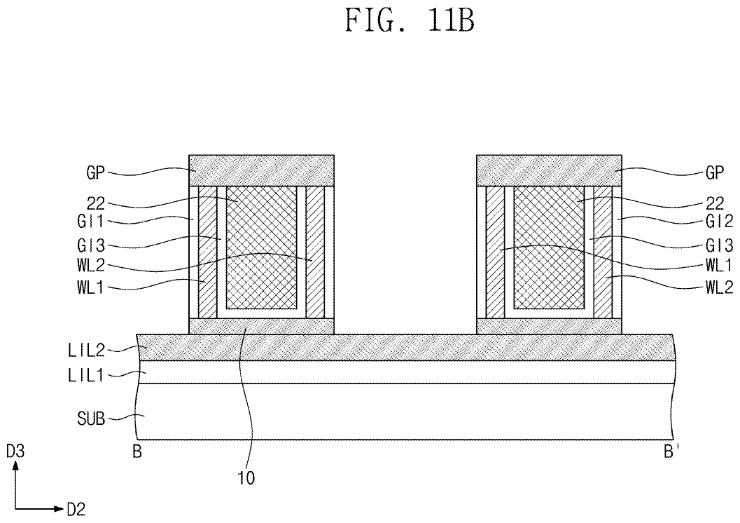

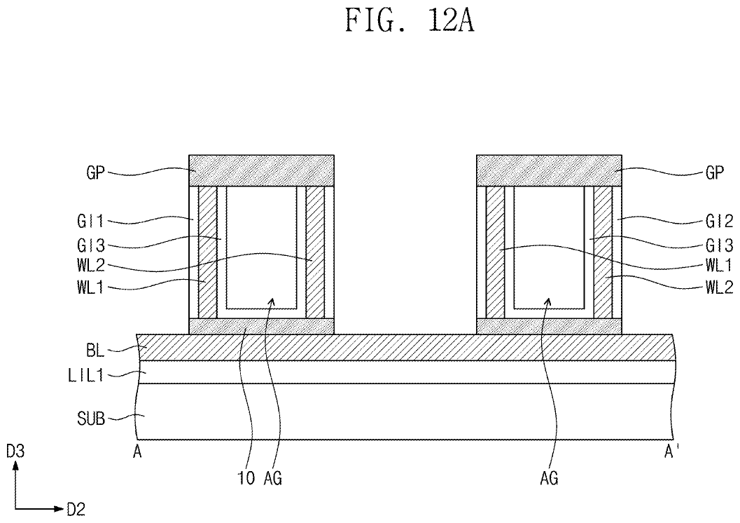

Referring to FIGS. 11A and 11B, there may be formed gate capping layers GP, first gate dielectric layers GI1, second gate dielectric layers GI2, and support dielectric layers 10.

In some embodiments, the formation of the gate capping layers GP, the first gate dielectric layers GI1, the second gate dielectric layers GI2, and the support dielectric layers 10 may include forming photoresist patterns on the preliminary gate capping layer pGP, and using the photoresist patterns to sequentially pattern the preliminary gate capping layer pGP, the preliminary gate dielectric patterns pGIP, and the preliminary support dielectric layer p10.

The preliminary gate capping layer pGP may be patterned and divided into gate capping layers GP. The preliminary gate dielectric pattern pGIP may be patterned and divided into the first gate dielectric layer GI1 and the second gate dielectric layer GI2. The preliminary support dielectric layer p10 may be patterned and divided into support dielectric layers 10. The preliminary support dielectric layer p10 may be patterned to expose a top surface of the bit line BL.

Before or simultaneously with the pattering the preliminary gate dielectric pattern pGIP, the first sacrificial layer 21 may be removed from the preliminary gate dielectric pattern pGIP. The first sacrificial layer 21 may remain on the third gate dielectric layer GI3. A second sacrificial layer 22 may be defined to refer to the first sacrificial layer 21 that remains on the third gate dielectric layer GI3.

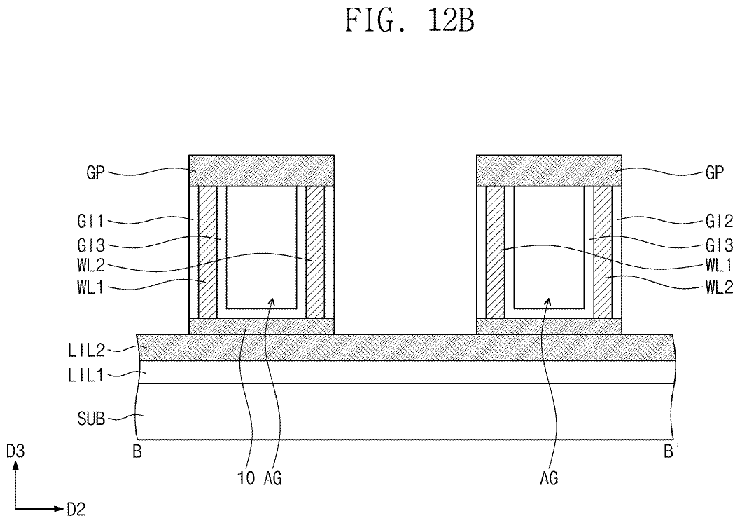

Referring to FIGS. 12A and 12B, the second sacrificial layers 22 may be removed. The second sacrificial layers 22 may be removed to form cavities or air gaps AG. In some embodiments, the second sacrificial layers 22 may be removed by an ashing process or a strip process.

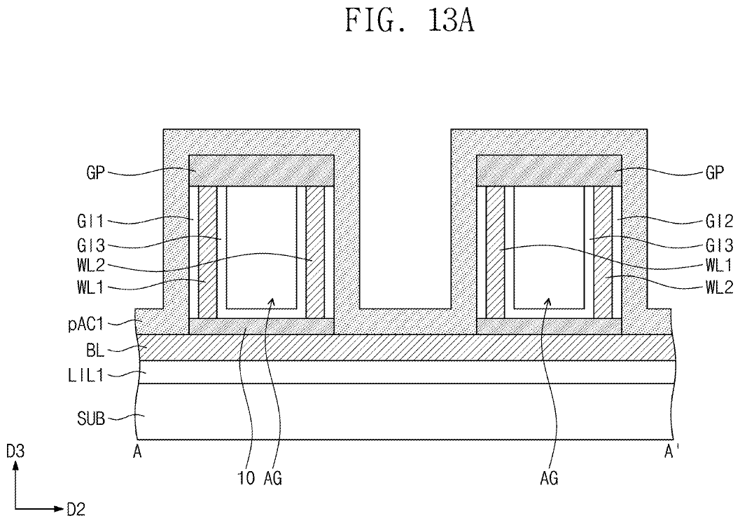

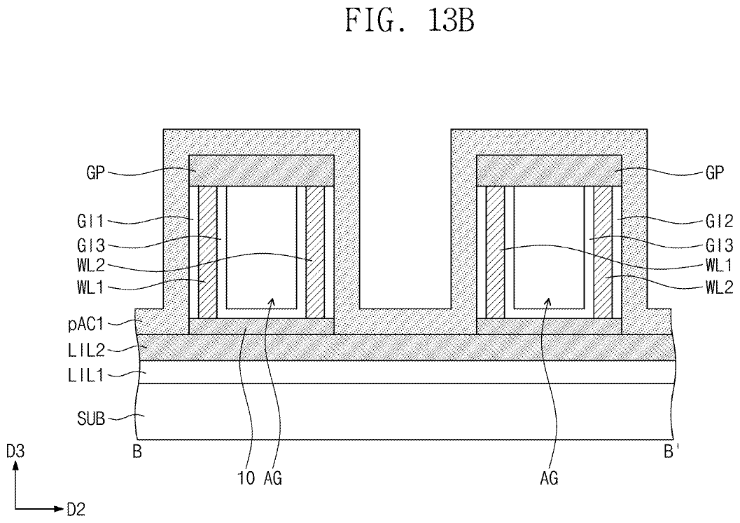

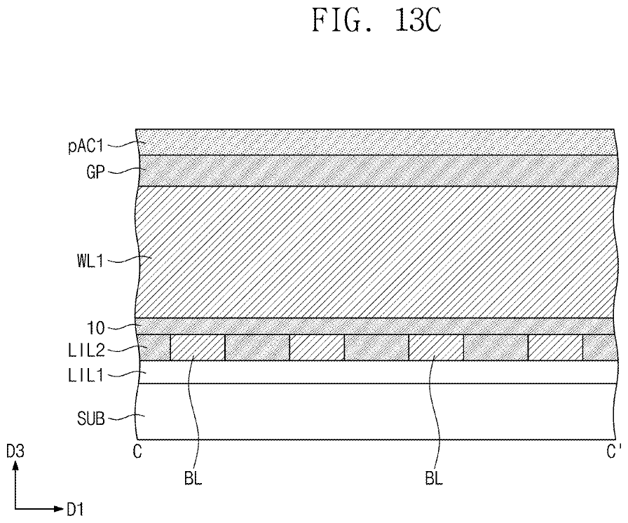

Referring to FIGS. 13A, 13B, and 13C, a first preliminary channel layer pAC1 may be formed. The first preliminary channel layer pAC1 may be conformally formed on the second lower dielectric layer LIL2, the bit lines BL, the first, second, and third gate dielectric layers GI1, GI2, and GI3, the support dielectric layers 10, and the gate capping layers GP.

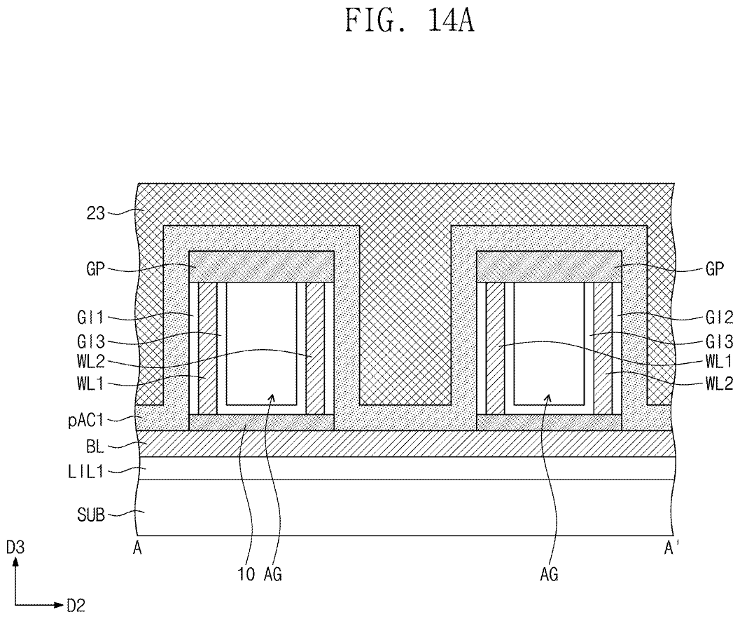

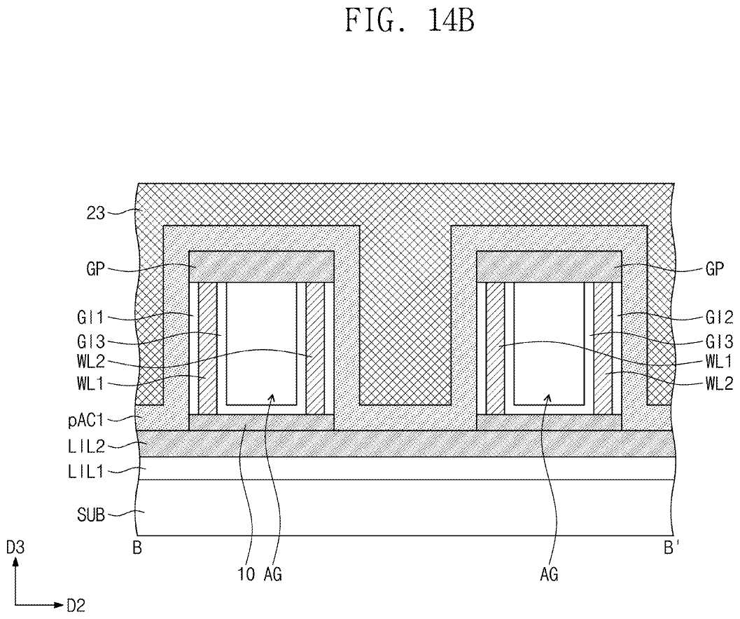

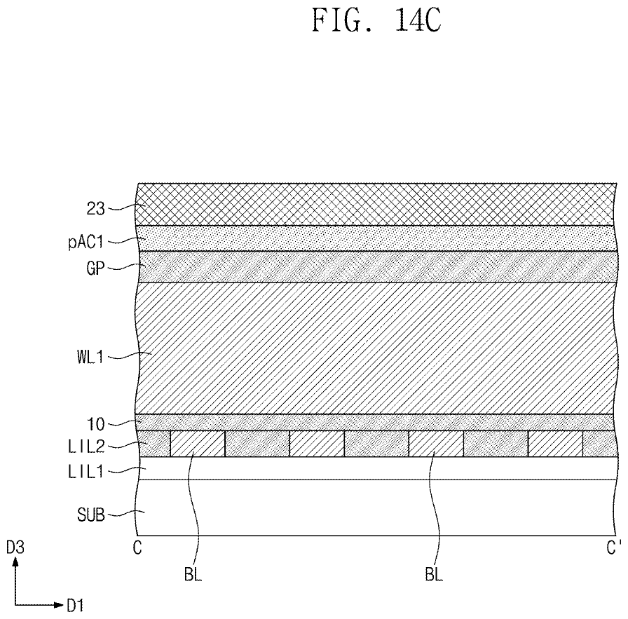

Referring to FIGS. 14A, 14B, and 14C, a third sacrificial layer 23 may be formed on the first preliminary channel layer pAC1. The third sacrificial layer 23 may include a dielectric material. For example, the third sacrificial layer 23 may include SOH.

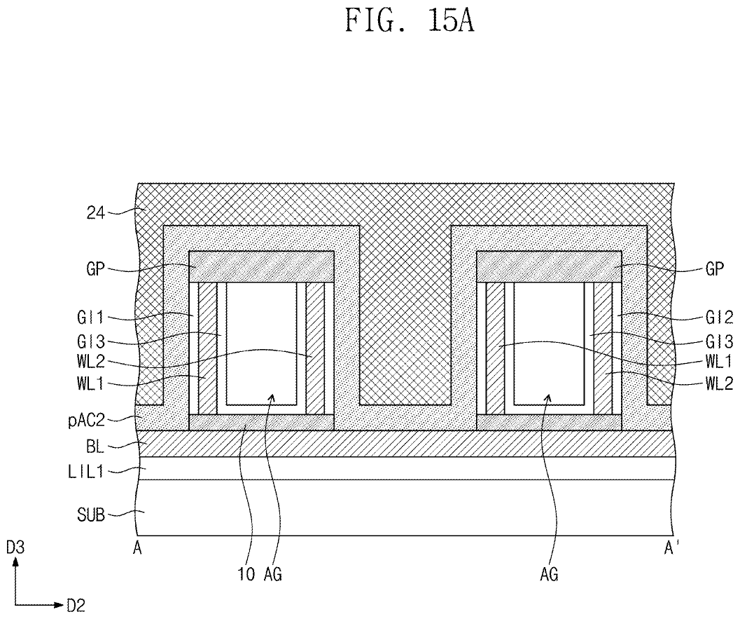

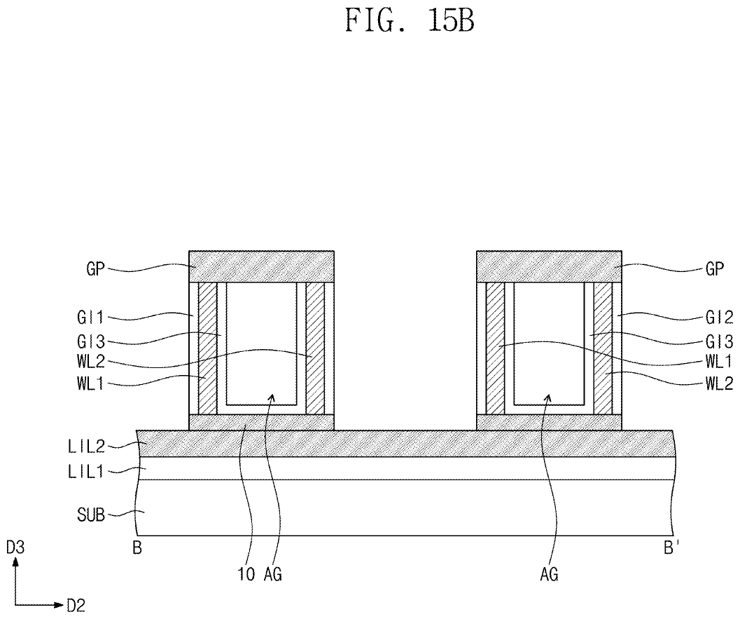

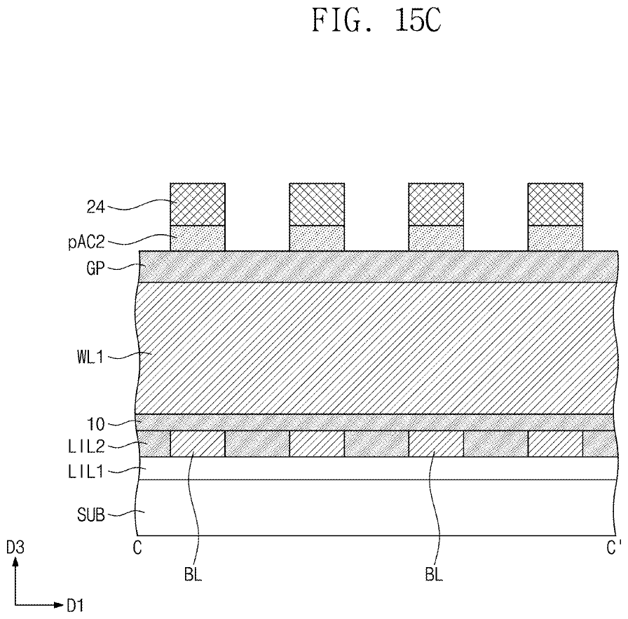

Referring to FIGS. 15A, 15B, and 15C, fourth sacrificial layers 24 and second preliminary channel layers pAC2 may be formed. In some embodiments, the formation of the fourth sacrificial layers 24 and the second preliminary channel layers pAC2 may include forming photoresist patterns on the third sacrificial layer 23, and using the photoresist patterns to sequentially pattern the third sacrificial layer 23 and the first preliminary channel layer pAC1.

The third sacrificial layer 23 may be patterned and divided into fourth sacrificial layers 24. The fourth sacrificial layers 24 may be arranged along a first direction D1. The first preliminary channel layer pAC1 may be patterned and divided into second preliminary channel layers pAC2. The second preliminary channel layers pAC2 may be arranged along the first direction D1. The first preliminary channel layer pAC1 may be patterned to expose the second lower dielectric layer LIL2.

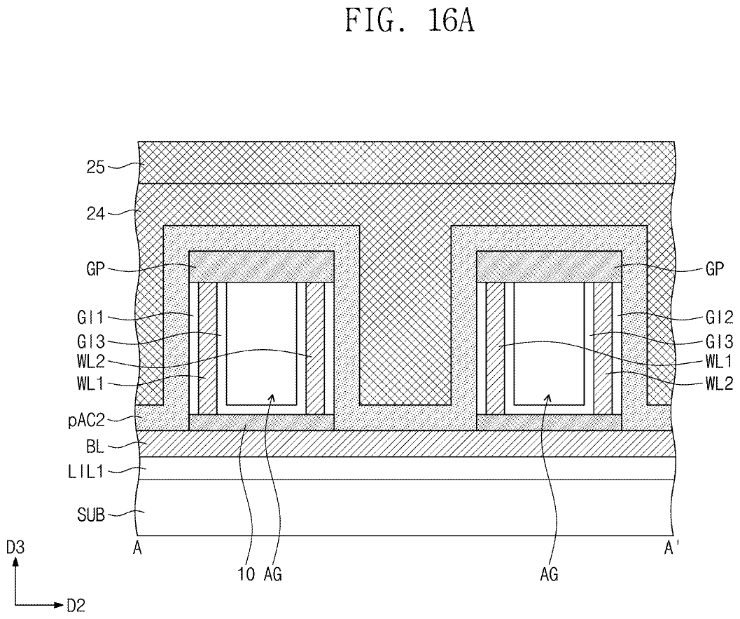

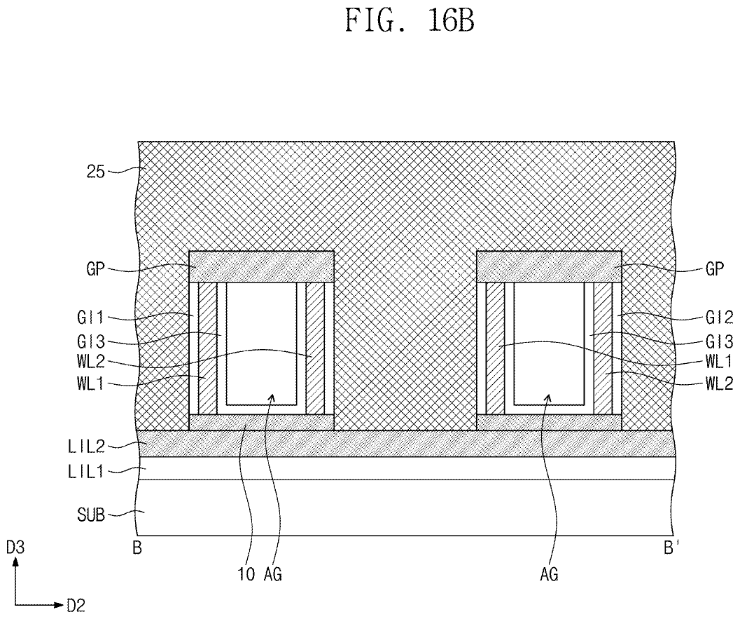

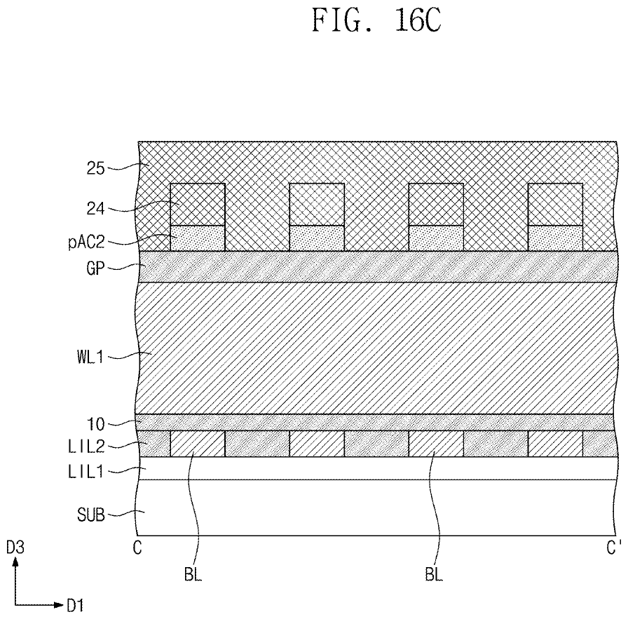

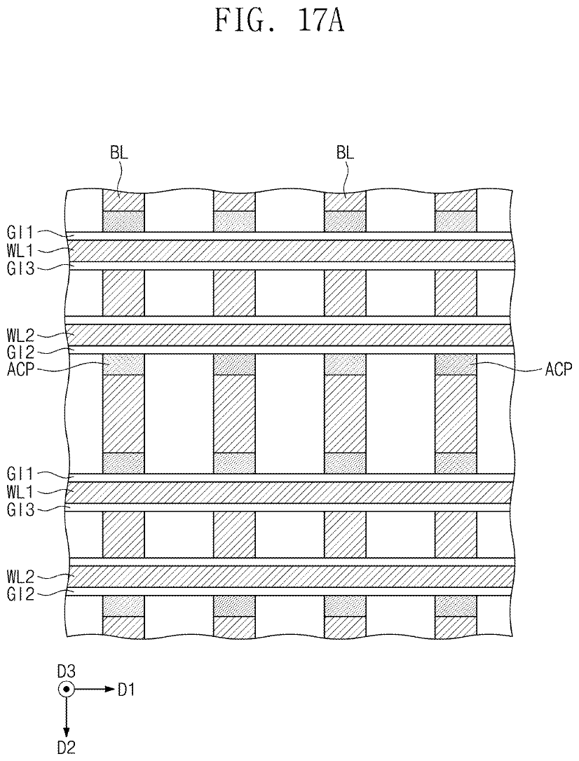

Referring to FIGS. 16A, 16B, and 16C, a fifth sacrificial layer 25 may be formed. The fifth sacrificial layer 25 may cover or overlap the fourth sacrificial layers 24, the second preliminary channel layers pAC2, the gate capping layers GP, and the second lower dielectric layer LIL2. The fifth sacrificial layer 25 may include a dielectric material. For example, the fifth sacrificial layer 25 may include SOH.

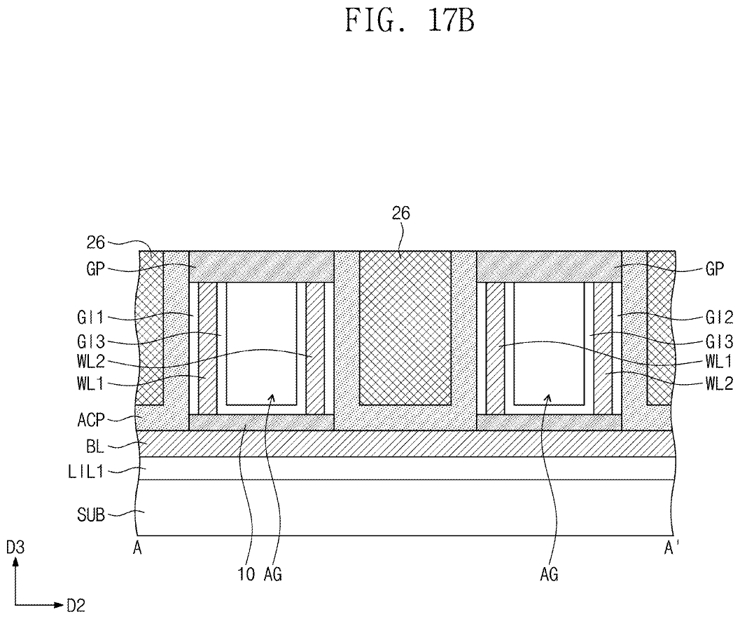

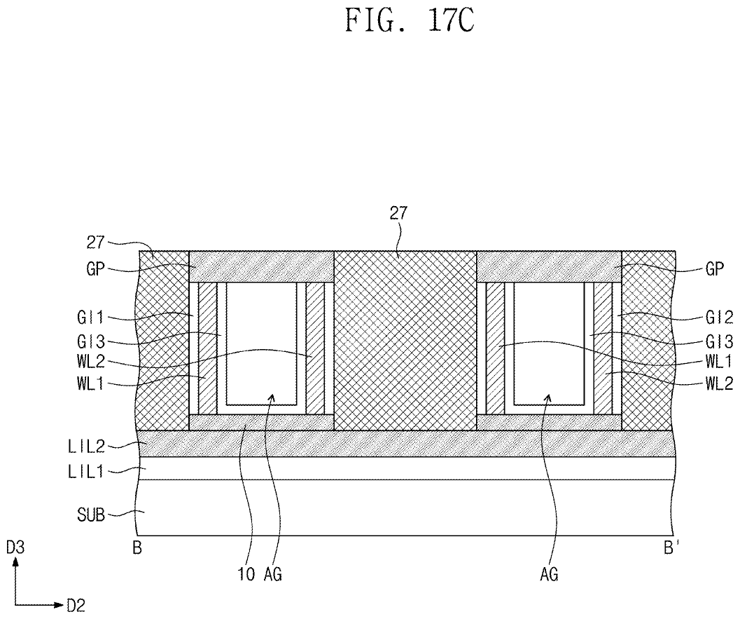

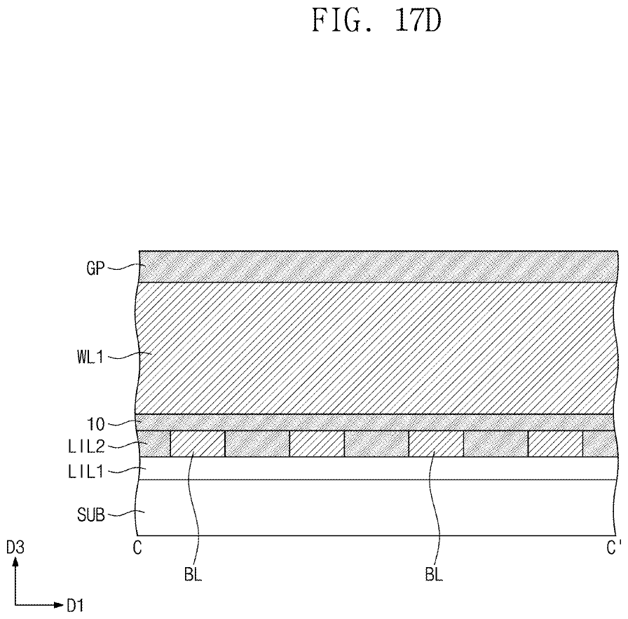

Referring to FIGS. 17A, 17B, 17C, and 17D, there may be formed channel layers ACP, sixth sacrificial layers 26, and seventh sacrificial layers 27. The formation of the channel layers ACP, the sixth sacrificial layers 26, and the seventh sacrificial layers 27 may include removing upper portions of the fourth sacrificial layers 24, an upper portion of the fifth sacrificial layer 25, and upper portions of the second preliminary channel layers pAC2 thereof. In some embodiments, a chemical mechanical polishing process may be employed to remove the upper portions of the fourth sacrificial layers 24, the upper portion of the fifth sacrificial layer 25, and the upper portions of the second preliminary channel layers pAC2.

The upper portion of the fourth sacrificial layer 24 may be removed such that the fourth sacrificial layer 24 may be divided into the sixth sacrificial layers 26. The upper portion of the fifth sacrificial layer 25 may be removed such that the fifth sacrificial layer 25 may be divided into the seventh sacrificial layers 27. The upper portion of the second preliminary channel layer pAC2 may be removed such that the second preliminary channel layer pAC2 may be divided into the channel layers ACP. The sixth sacrificial layer 26 may be disposed on the channel layer ACP. The seventh sacrificial layer 27 may be disposed on the second lower dielectric layer LIL2.

The upper portions of the fourth sacrificial layers 24, the upper portion of the fifth sacrificial layer 25, and the upper portions of the second preliminary channel layers pAC2 may be removed to expose the gate capping layers GP.

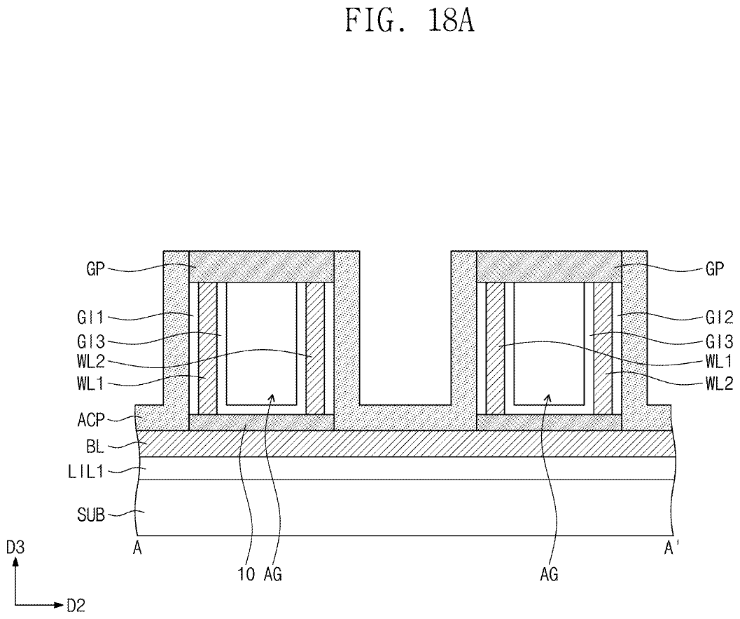

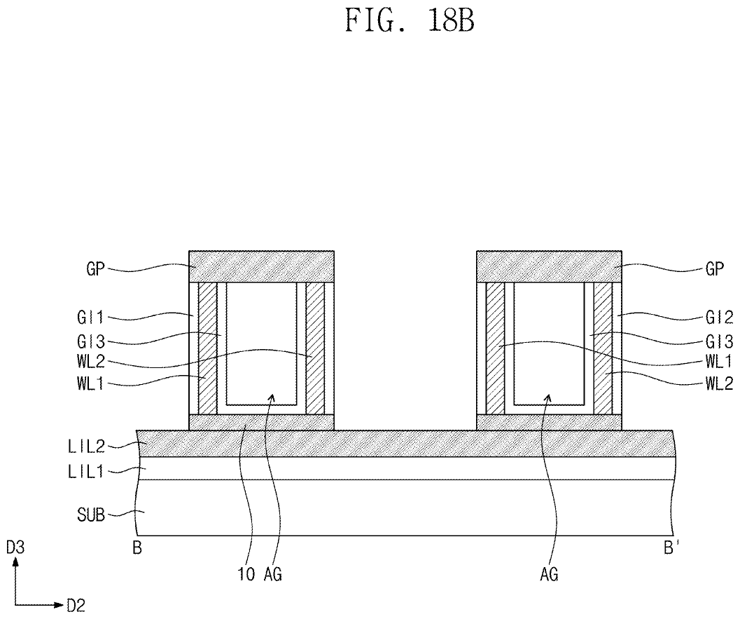

Referring to FIGS. 18A and 18B, the sixth sacrificial layers 26 and the seventh sacrificial layers 27 may be removed. In some embodiments, an ashing process may be used to remove the sixth sacrificial layers 26 and the seventh sacrificial layers 27.

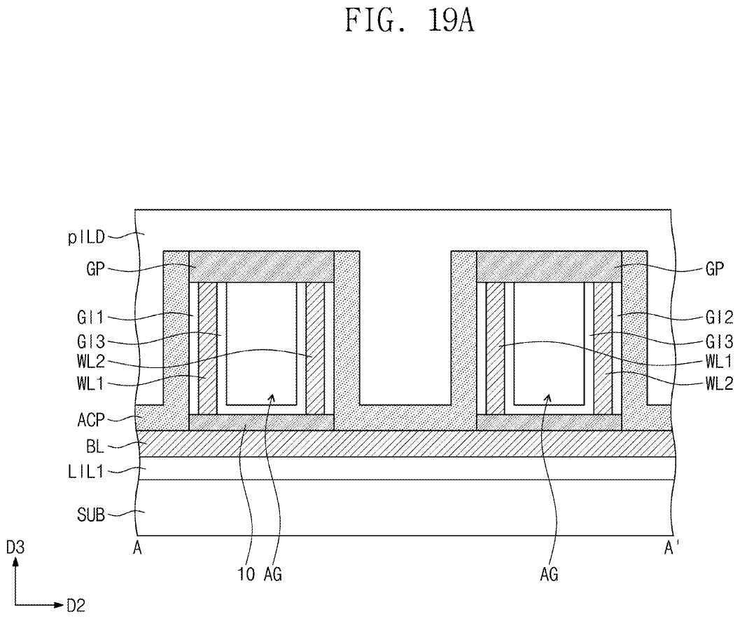

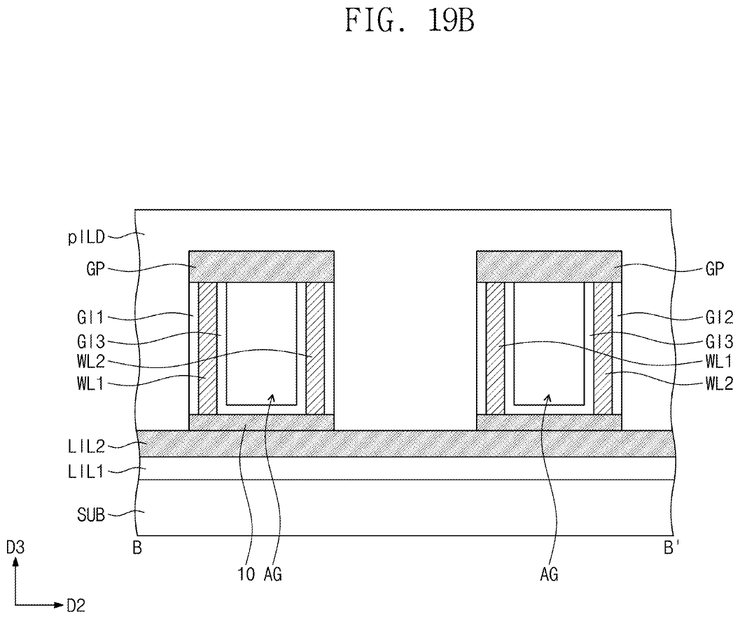

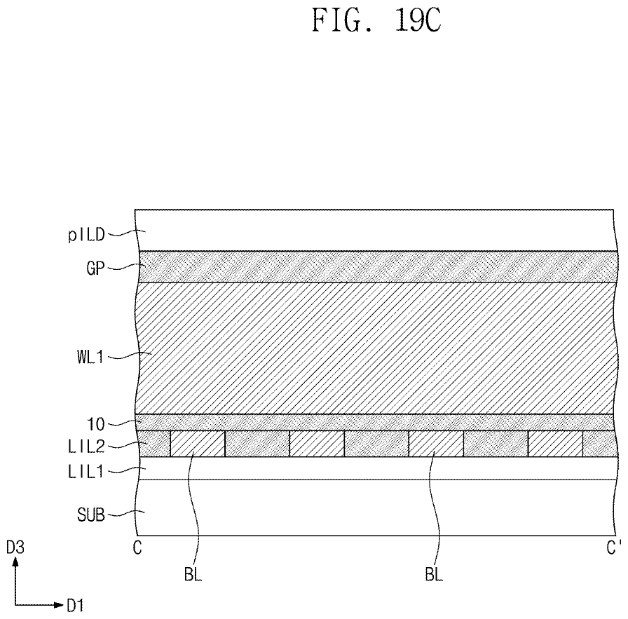

Referring to FIGS. 19A, 19B, and 19C, a preliminary dielectric layer pILD may be formed. The preliminary dielectric layer pILD may cover or overlap the channel layers ACP, the gate capping layers GP, and the second lower dielectric layer LIL2. The preliminary dielectric layer pILD may include a dielectric material. For example, the preliminary dielectric layer pILD may include oxide.

Referring to FIGS. 4A, 4B, 4C, and 4D, an upper portion of the preliminary dielectric layer pILD may be removed. The upper portion of the preliminary dielectric layer pILD may be removed such that the preliminary dielectric layer pILD may be divided into dielectric layers ILD. An upper portion of the channel layer ACP may be removed.

Landing pads LP and dielectric patterns INP may be formed. The landing pad LP may fill an empty space formed by the removal of the upper portion of the channel layer ACP. There may be formed data storage patterns DSP that are correspondingly connected to the landing pads LP.

In a method of fabricating a semiconductor device according to some embodiments, the landing pad LP may be formed in a state that the first, second, and third gate dielectric layers GI1, GI2, and GI3 are protected by the dielectric layers ILD and the channel layers ACP, and thus the first, second, and third gate dielectric layers GI1, GI2, and GI3 may be prevented from being damaged in a process for forming the landing pad LP.

In a method of fabricating a semiconductor device according to some embodiments, the first, second, and third gate dielectric layers GI1, GI2, and GI3 may be formed after the first and second word lines WL1 and WL2 are formed, and thus the first, second, and third gate dielectric layers GI1, GI2, and GI3 may be restricted or prevented from being damaged.

In a method of fabricating a semiconductor device according to some embodiments, the first, second, and third gate dielectric layers GI1, GI2, and GI3 may be formed through a single deposition process, and thus the first, second, and third gate dielectric layers GI1, GI2, and GI3 may have a relatively small number of interfaces therein and may increase in reliability.

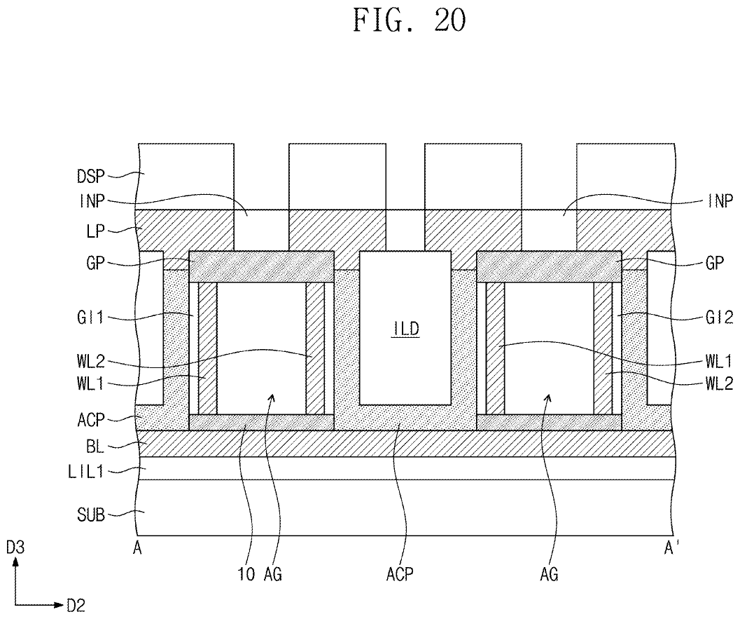

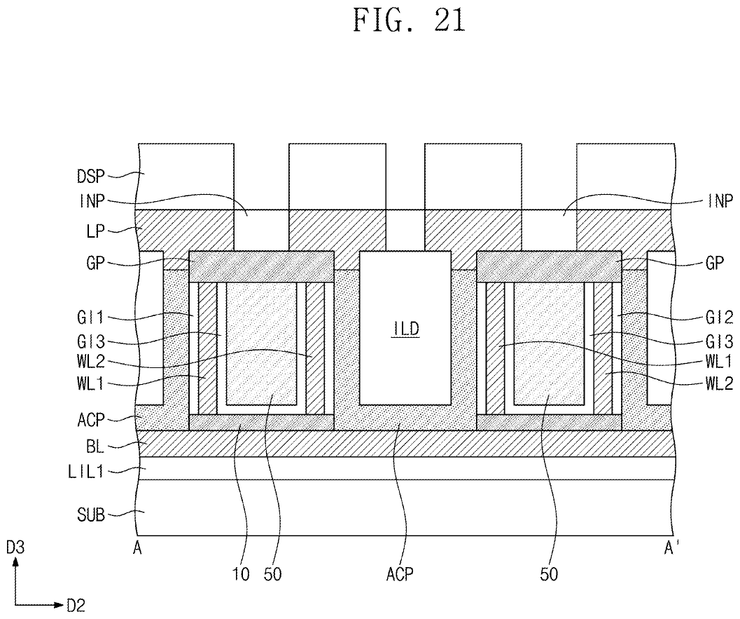

FIG. 20 illustrates a cross-sectional view showing a semiconductor device according to some embodiments.

Referring to FIG. 20, a semiconductor device may include a cavity or an air gap AG defined between the first word line WL1 and the second word line WL2. The air gap AG may have a bottom surface defined by the top surface of the support dielectric layer 10. The air gap AG may have sidewalls defined by sidewalls of the first and second word lines WL1 and WL2. No gate dielectric layer may be present between the first and second word lines WL1 and WL2.

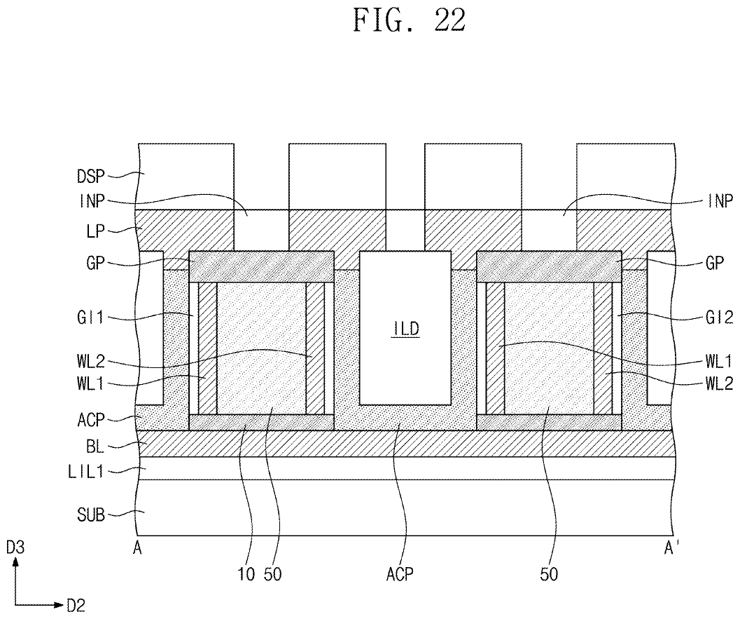

FIG. 21 illustrates a cross-sectional view showing a semiconductor device according to some embodiments.

Referring to FIG. 21, a semiconductor device may include a low-k material layer 50 on the third gate dielectric layer GI3. The low-k material layer 50 may have a bottom surface and sidewalls in contact with the third gate dielectric layer GI3. The low-k material layer 50 may have a top surface in contact with the gate capping layer GP. The low-k material layer 50 may include a material whose dielectric constant is less than those of the dielectric layer ILD, the first, second, and third gate dielectric layers GI1, GI2, and GI3, the support dielectric layer 10, and the gate capping layer GP.

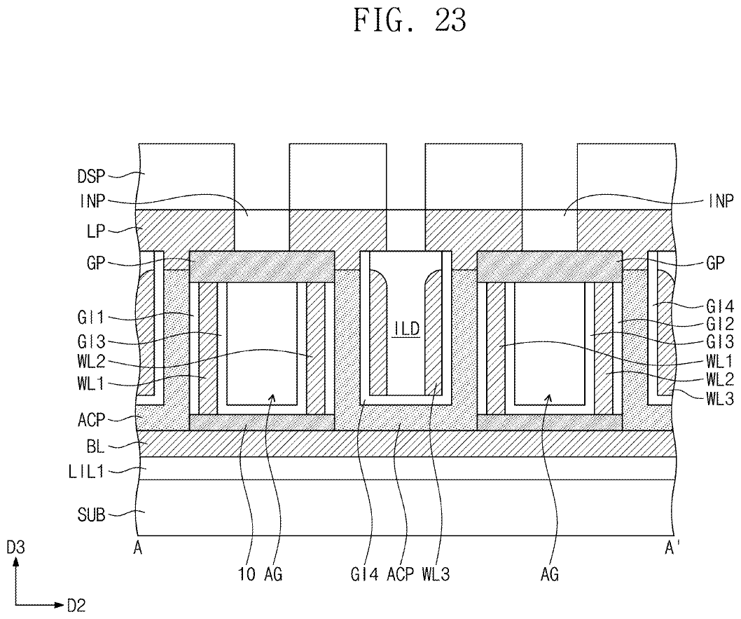

FIG. 22 illustrates a cross-sectional view showing a semiconductor device according to some embodiments.

Referring to FIG. 22, a semiconductor device may include a low-k material layer 50 on the support dielectric layer 10. The low-k material layer 50 may have a bottom surface in contact with the top surface of the support dielectric layer 10. The low-k material layer 50 may have sidewalls in contact with sidewalls of the first and second word lines WL1 and WL2. The low-k material layer 50 may have a top surface in contact with the gate capping layer GP. The low-k material layer 50 may include a material whose dielectric constant is less than those of the dielectric layer ILD, the first, second, and third gate dielectric layers GI1, GI2, and GI3, the support dielectric layer 10, and the gate capping layer GP.

FIG. 23 illustrates a cross-sectional view showing a semiconductor device according to some embodiments.

Referring to FIG. 23, a semiconductor device may include a fourth gate dielectric layer GI4 on the channel layer ACP and third word lines WL3 on the fourth gate dielectric layer GI4. The third word lines WL3 may be spaced apart from each other across the dielectric layer ILD. The fourth gate dielectric layer GI4 may be in contact with the landing pad LP.

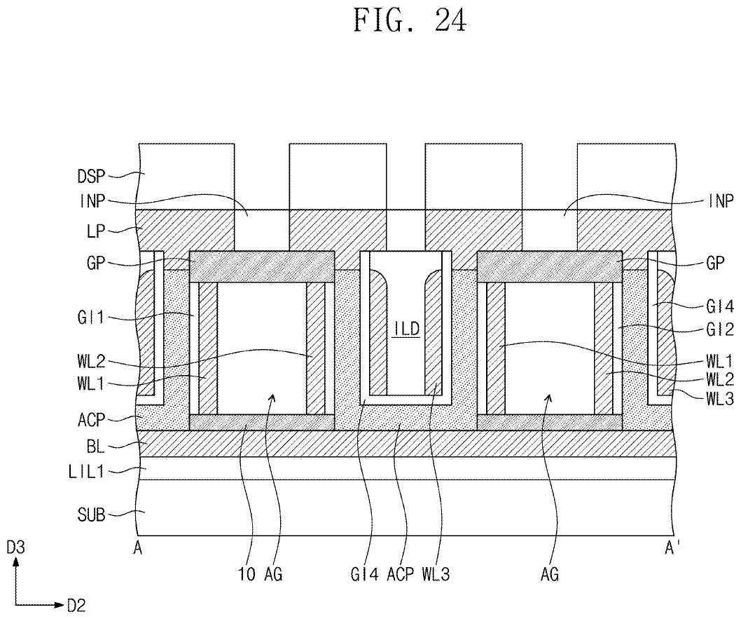

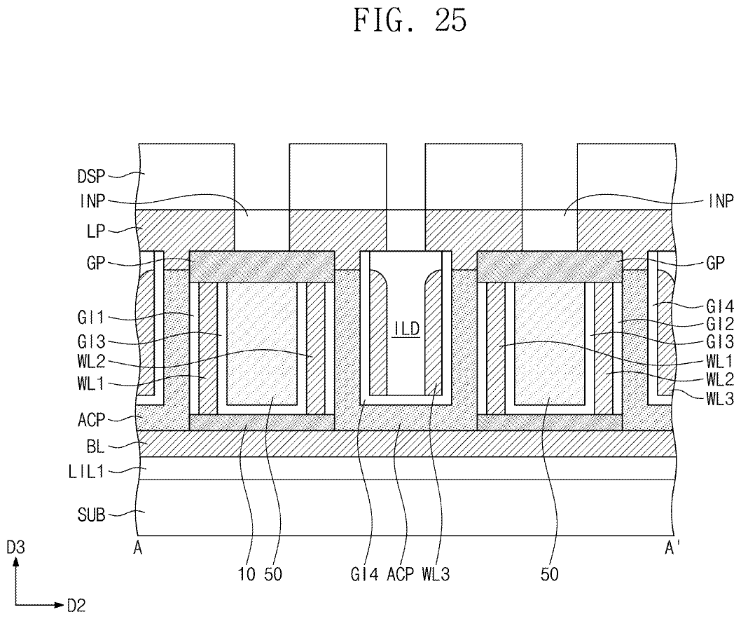

FIG. 24 illustrates a cross-sectional view showing a semiconductor device according to some embodiments.

Referring to FIG. 24, a semiconductor device may include a fourth gate dielectric layer GI4 on the channel layer ACP and third word lines WL3 on the fourth gate dielectric layer GI4.

The cavity or air gap AG may have a bottom surface defined by the top surface of the support dielectric layer 10. The air gap AG may have sidewalls defined by sidewalls of the first and second word lines WL1 and WL2.

FIG. 25 illustrates a cross-sectional view showing a semiconductor device according to some embodiments.

Referring to FIG. 25, a semiconductor device may include a fourth gate dielectric layer GI4 on the channel layer ACP and third word lines WL3 on the fourth gate dielectric layer GI4. A low-k material layer 50 may be provided on the third gate dielectric layer GI3.

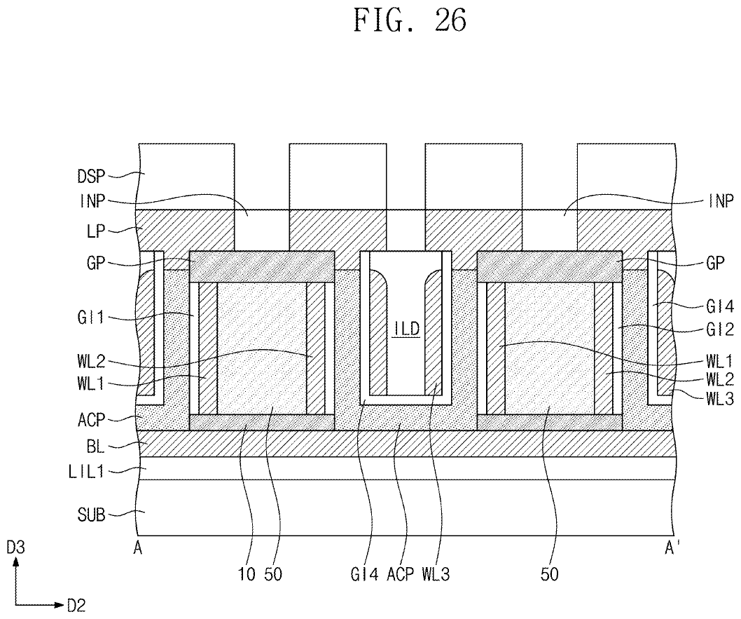

FIG. 26 illustrates a cross-sectional view showing a semiconductor device according to some embodiments.

Referring to FIG. 26, a semiconductor device may include a fourth gate dielectric layer GI4 on the channel layer ACP, and may also include third word lines WL3 on the fourth gate dielectric layer GI4. A low-k material layer 50 may be provided on the support dielectric layer 10.

In a semiconductor device according to some embodiments of the present inventive concepts, as a gate dielectric layer is formed after a word line is formed, the gate dielectric layer may be restricted or prevented from being damaged.

In a semiconductor device according to some embodiments of the present inventive concepts, as a gate dielectric layer is protected in a process for forming a landing pad, the gate dielectric layer may be restricted or prevented from being damaged.

In a semiconductor device according to some embodiments of the present inventive concepts, as a gate dielectric layer is formed through a single deposition process, the gate dielectric layer may have a relatively small number of interfaces therein and may thus increase in reliability.

In a semiconductor device according to some embodiments of the present inventive concepts, as a cavity, an air gap or a low-k material layer is provided between word lines, there may be a reduction in parasitic capacitance between the word lines and an improvement in alternating current properties of the semiconductor device.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts.

What is claimed is:

1. A semiconductor device, comprising:
a bit line;
a support dielectric layer on the bit line;
a first word line and a second word line on the support dielectric layer;
a first gate dielectric layer on a first sidewall of the first word line;
a second gate dielectric layer on a first sidewall of the second word line; and
channel layers that are spaced apart from one another,
wherein the support dielectric layer, the first word line, the second word line, the first gate dielectric layer, and the second gate dielectric layer are between a first one of the channel layers and a second one of the channel layers.

2. The semiconductor device of claim 1, further comprising:
a third gate dielectric layer in contact with a second sidewall of the first word line and a second sidewall of the second word line,
wherein the first and second sidewalls of the first word line are opposite to one another, and the first and second sidewalls of the second word line are opposite to one another.

3. The semiconductor device of claim 2, wherein the third gate dielectric layer comprises:
a first portion in contact with the second sidewall of the first word line;
a second portion in contact with the second sidewall of the second word line; and
a third portion in contact with a top surface of the support dielectric layer.

4. The semiconductor device of claim 3,
wherein a cavity is surrounded by the first, second, and third portions of the third gate dielectric layer.

5. The semiconductor device of claim 1, further comprising:
a gate capping layer on the first word line and the second word line.

6. The semiconductor device of claim 5, wherein the gate capping layer is in contact with a top surface of the first gate dielectric layer and a top surface of the second gate dielectric layer.

7. The semiconductor device of claim 1, wherein each of the channel layers comprises:
a lower channel portion in contact with the bit line; and
a plurality of upper channel portions on the lower channel portion,
wherein the upper channel portions are spaced apart from each other.

8. The semiconductor device of claim 7, further comprising:
a dielectric layer in contact with sidewalls of the upper channel portions and a top surface of the lower channel portion.

9. The semiconductor device of claim 7, further comprising:
a third gate dielectric layer in contact with sidewalls of the upper channel portions and a top surface of the lower channel portion; and
a third word line on the third gate dielectric layer.

10. A semiconductor device, comprising:
a plurality of gate structures;
a channel layer between a first one of the plurality of gate structures and a second one of the plurality of gate structures; and
a bit line in contact with the channel layer,
wherein each of the plurality of gate structures comprises:
a first word line and a second word line that are spaced apart from each other;
a first gate dielectric layer on a first sidewall of the first word line;
a second gate dielectric layer on a first sidewall of the second word line; and
a gate capping layer in contact with a top surface of the first word line, a top surface of the second word line, a top surface of the first gate dielectric layer, and a top surface of the second gate dielectric layer.

11. The semiconductor device of claim 10, wherein the top surface of the first word line, the top surface of the second word line, the top surface of the first gate dielectric layer, and the top surface of the second gate dielectric layer are coplanar with each other.

12. The semiconductor device of claim 10,
wherein each of the plurality of gate structures further comprises a third gate dielectric layer between the first word line and the second word line,
wherein the third gate dielectric layer comprises:
a first portion in contact with a second sidewall of the first word line;
a second portion in contact with a second sidewall of the second word line; and
a third portion that connects the first and second portions to each other, and
wherein the first and second sidewalls of the first word line are opposite to one another, and the first and second sidewalls of the second word line are opposite to one another.

13. The semiconductor device of claim 12, wherein a top surface of the first portion of the third gate dielectric layer and a top surface of the second portion of the third gate dielectric layer are in contact with the gate capping layer.

14. The semiconductor device of claim 12, further comprising:
a low-k material layer on the third gate dielectric layer,
wherein the low-k material layer is between the first word line and the second word line.

15. The semiconductor device of claim 10,
wherein each of the plurality of gate structures further comprises a support dielectric layer in contact with a top surface of the bit line, and
wherein the first word line, the second word line, the first gate dielectric layer, and the second gate dielectric layer are in contact with a top surface of the support dielectric layer.

16. The semiconductor device of claim 15,
wherein a cavity is between the first word line and the second word line,
wherein the cavity is between a second sidewall of the first word line and a second sidewall of the second word line, and
wherein the cavity is on the top surface of the support dielectric layer.

17. The semiconductor device of claim 16, wherein the cavity is on a bottom surface of the gate capping layer.

18. The semiconductor device of claim 10, wherein the top surface of the first word line, the top surface of the second word line, the top surface of the first gate dielectric layer, and the top surface of the second gate dielectric layer are at respective heights that are lower than a height of a top surface of the channel layer with respect to the bit line.

19. A semiconductor device, comprising:
a bit line;
a gate structure on the bit line;
channel layers that are spaced apart from each other with the gate structure between a first one of the channel layers and a second one of the channel layers;
a landing pad electrically connected to at least one of the channel layers; and
a data storage pattern electrically connected to the landing pad,
wherein the gate structure comprises:
a support dielectric layer on the bit line;
a first word line and a second word line that are spaced apart from each other on the support dielectric layer;
a first gate dielectric layer on a sidewall of the first word line;
a second gate dielectric layer on a sidewall of the second word line; and
a gate capping layer in contact with the first word line, the second word line, the first gate dielectric layer, and the second gate dielectric layer.

20. The semiconductor device of claim 19, wherein the landing pad is spaced apart from the first and second gate dielectric layers.
